(19) United States
(12) Patent Application Publication
(10) Pub. No.: US 2023/0296684 A1
(43) Pub. Date: Sep. 21, 2023

(54) Accelerated Battery Lifetime Simulations Using Adaptive Inter-Cycle Extrapolation Algorithm

(71) Applicant: The Regents of The University of Michigan, Ann Arbor, MI (US)

(72) Inventors: Anna Stefanopoulou, Ann Arbor, MI (US); Valentin Sulzer, Ann Arbor, MI (US); Peyman Mohtat, Ann Arbor, MI (US); Sravan Pannala, Ann Arbor, MI (US); Jason Siegel, Ann Arbor, MI (US)

(21) Appl. No.: 18/122,361

(22) Filed: Mar. 16, 2023

Related U.S. Application Data
(60) Provisional application No. 63/321,402, filed on Mar. 18, 2022.

(51) Int. Cl. G01R 31/385; G01R 31/367; G01R 31/396; G01R 31/392

(52) U.S. Cl. CPC G01R 31/3865; G01R 31/367; G01R 31/396; G01R 31/392

(57) ABSTRACT

Disclosed is a method for manufacturing an electrochemical cell wherein the cell undergoes degradation that results in loss of active material and cation inventory during charging phase(s) of cell cycles. The method comprises: selecting at least one cell component from electrolytes, cathode active materials, and anode active materials; sequentially calculating a cell capacity at an end of each of a plurality of cell cycles based on total cyclable cations, accessible storage sites in each electrode, and the cell component(s) using a degradation model based on porous-electrode theory and having degradation pathway(s), wherein the cell cycles are initialized based on a rate of degradation over previous cycles and wherein a time at which to simulate the next cycle is chosen based on the rate of degradation over the previous cycles; and predicting end of life of the cell based on one of the calculated cell capacities being less than a percentage of nominal capacity.

### CROSS-REFERENCES TO RELATED APPLICATIONS

This application claims priority to U.S. Patent Application No. 63/321,402 filed Mar. 18, 2022.

### STATEMENT REGARDING FEDERALLY SPONSORED RESEARCH

This invention was made with government support under Grant Number 1762247 awarded by the National Science Foundation. The U.S. government has certain rights in the invention.

### BACKGROUND OF THE INVENTION

### 1. Field of the Invention

This invention relates to a methods for speeding up battery lifetime prediction systems so that manufacturers can accelerate the battery cell development process.

### 2. Description of the Related Art

With the increasing demand for electric vehicles, global lithium-ion battery manufacturing capacity is quickly approaching the terawatt-hour scale. Lithium-ion batteries are deployed in a wide range of applications due to their low and falling costs, high energy densities, and long cycle lives. Batteries for light duty vehicles and grid applications are often made to last and warranted for 8-10 years. Improved understanding of battery degradation can lead to better reliability, safety, extended utilization of batteries, and hence reduced costs. However, battery degradation can therefore take around ten years in the field, which is prohibitively long for understanding the effect of a battery design parameter change on lifetime.

The total testing time for a battery cycle life prediction is often reduced in the lab by using accelerated aging conditions and skipping rest between cycles, degrading the battery in a few months. To reduce the time further, modeling is required. In particular, physics-based electrochemical models that embed degradation mechanisms are useful for evaluating the capacity and power fade of lithium-ion batteries under various duty cycles, and hence predicting their lifetime, since they can directly simulate a wide range of realistic battery uses at various scales. However, physics-based simulations of the entire battery lifetime typically take several minutes to hours. For example, if a simulation of one full charge/discharge cycle takes one second, simulating 1000 cycles would take around 15 minutes. This is much faster than experimental timescales, but still too slow and not ideal for rapid feedback and repeated simulations of the model, for example in a parameter estimation routine which require multiple forward solves of the model.

What is needed therefore are methods for speeding up battery lifetime prediction systems so that manufacturers can accelerate the battery cell development process.

### SUMMARY OF THE INVENTION

The present invention addresses the foregoing needs by providing methods for speeding up battery lifetime prediction systems so that manufacturers can accelerate the battery cell development process.

In one aspect, the disclosure provides a method for manufacturing an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles. The method comprises: (a) selecting at least one cell component selected from the group consisting of electrolytes, cathode active materials, and anode active materials, the at least one cell component causing the degradation of the cell; (b) determining a nominal discharge capacity for the cell at a state of health of 100%; (c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the cell cycles are initialized based on a rate of degradation over a plurality of previous cycles and wherein a time at which to simulate the next cycle is chosen based on the rate of degradation over the plurality of previous cycles; and (d) determining a predicted end of life of the electrochemical cell based on one of the calculated cell capacities being less than a predetermined percentage of the nominal capacity.

In another aspect, the disclosure provides a method for manufacturing an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles. The method comprises: (a) selecting at least one cell component selected from the group consisting of electrolytes, cathode active materials, and anode active materials, the at least one cell component causing the degradation of the cell; (b) determining a nominal discharge capacity for the cell at a state of health of 100%; (c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the model uses a current density of cation intercalation as a variable without use of a current density of solid electrolyte interphase formation as a variable; and (d) determining a predicted end of life of the electrochemical cell based on one of the calculated cell capacities being less than a predetermined percentage of the nominal capacity.

In another aspect, the disclosure provides a method for manufacturing an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles. The method comprises: (a) selecting at least one cell component selected from the group consisting of electrolytes, cathode active materials, and anode active materials, the at least one cell component causing the degradation of the cell; (b) determining a nominal discharge capacity for the cell at a state of health of 100%; (c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the model uses a current density of cation intercalation as a variable without use of a current density of cation plating as a variable; and (d) determining a predicted end of life of the electrochemical cell based on one of the calculated cell capacities being less than a predetermined percentage of the nominal capacity.

In one version of any of these methods for manufacturing an electrochemical cell, the model does not include an algebraic equation. In one version of any of these methods for manufacturing an electrochemical cell, sequentially calculating the cell capacity at the end of each of the plurality of cell cycles is at least three times faster than a degradation model based on porous-electrode theory that includes an algebraic equation.

In one version of any of these methods for manufacturing an electrochemical cell, the model does not include an algebraic equation for calculating a surface potential difference (Φ_{s,n}−Φₑ) where Φ_{s,n} denotes a potential of a solid phase of the anode, and Φₑ denotes a potential of a phase of the electrolyte.

In one version of any of these methods for manufacturing an electrochemical cell, step (c) comprises sequentially calculating the cell capacity at the end of each of the plurality of cell cycles based on a solid electrolyte interphase kinetic rate constant (k_{SEI}), a solid electrolyte interphase layer diffusivity (D_{SEI}), and an active material particle cracking rate (β_{LAM}). Step (c) can comprise tuning the solid electrolyte interphase kinetic rate constant, the solid electrolyte interphase layer diffusivity, and the active material particle cracking rate to create a linear degradation path for the calculated cell capacities of the plurality of cell cycles. Step (c) can comprise tuning the solid electrolyte interphase kinetic rate constant, the solid electrolyte interphase layer diffusivity, and the active material particle cracking rate to create a self-limiting degradation path for the calculated cell capacities of the plurality of cell cycles. Step (c) can comprise tuning the solid electrolyte interphase kinetic rate constant, the solid electrolyte interphase layer diffusivity, and the active material particle cracking rate to create an accelerating degradation path for the calculated cell capacities of the plurality of cell cycles.

In one version of any of these methods for manufacturing an electrochemical cell, the method can further comprise: (e) selecting a different at least one cell component; (f) sequentially calculating a second cell capacity at an end of each of the plurality of cell cycles based on the different at least one cell component; (g) determining an additional predicted end of life of the electrochemical cell based on one of the calculated second cell capacities being less than the predetermined percentage of the nominal capacity; (h) comparing the predicted end of life and the additional predicted end of life and selecting a preferred cell having a greater predicted end of life of the predicted end of life and the additional predicted end of life; and (i) manufacturing the preferred cell.

In one version of any of these methods for manufacturing an electrochemical cell, calculating the cell capacity employs the relationship:

cell capacity=Cₙ(Θₙ¹⁰⁰−Θₙ⁰),

where Cₙ denotes a capacity of the anode, Θₙ¹⁰⁰ denotes a scaled volumed-averaged negative particle concentration at 100% State of Charge, and Θₙ⁰ denotes a scaled volumed-averaged negative particle concentration at 0% State of Charge.

In one version of any of these methods for manufacturing an electrochemical cell, step (c) comprises sequentially calculating the cell capacity at the end of at least a portion of the plurality of cell cycles based on the total cyclable cations, a solid electrolyte interphase thickness (δ_{SEI}), a porosity (ε_{s,n}) of a solid phase of the anode, and a porosity (ε_{s,p}) of a solid phase of the cathode.

In one version of any of these methods for manufacturing an electrochemical cell, the model does not include an algebraic equation for calculating a surface potential difference (Φ_{s,n}−Φₑ) where Φ_{s,n} denotes a potential of a solid phase of the anode, and Φₑ denotes a potential of a phase of the electrolyte.

In one version of any of these methods for manufacturing an electrochemical cell, the cations are lithium cations. In one version of any of these methods for manufacturing an electrochemical cell, the anode comprises an anode material selected from graphite, lithium titanium oxide, hard carbon, tin/cobalt alloys, silicon/carbon, or lithium metal; the electrolyte comprises a liquid electrolyte including a lithium compound in an organic solvent; and the cathode comprises a cathode active material selected from (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, and (iii) materials having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811).

In one version of any of these methods for manufacturing an electrochemical cell, the anode comprises graphite; the electrolyte comprises a liquid electrolyte including a lithium compound in an organic solvent, the lithium compound is selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf), the organic solvent is selected from carbonate based solvents, ether based solvents, ionic liquids, and mixtures thereof, the carbonate based solvent is selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate, and mixtures thereof, and the ether based solvent is selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane and mixtures thereof.

In another aspect, the disclosure provides a method for predicting an end of life of an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles. The method comprises: (a) selecting at least one cell component selected from the group consisting of electrolytes, cathode active materials, and anode active materials, the at least one cell component causing the degradation of the cell; (b) determining a nominal discharge capacity for the cell at a state of health of 100%; (c) sequentially calculating a cell capacity at an end of each of the plurality of cell cycles based on total cyclable cations (ηₛ), accessible storage sites in each electrode, and the at least one cell component using a degradation model based on porous-electrode theory and having one or more degradation pathways, wherein the cell cycles are initialized based on a rate of degradation over a plurality of previous cycles and wherein a time at which to simulate the next cycle is chosen based on the rate of degradation over the plurality of previous cycles; and (d) determining a predicted end of life of the electrochemical cell based on one of the calculated cell capacities being less than a predetermined percentage of the nominal capacity.

In another aspect, the disclosure provides a method for predicting an end of life of an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles. The method comprises: (a) selecting at least one cell component selected from the group consisting of electrolytes, cathode active materials, and anode active materials, the at least one cell component causing the degradation of the cell; (b) determining a nominal discharge capacity for the cell at a state of health of 100%; (c) sequentially calculating a cell capacity at an end of each of the plurality of cell cycles based on total cyclable cations (ηₛ), accessible storage sites in each electrode, and the at least one cell component using a degradation model based on porous-electrode theory and having one or more degradation pathways, wherein the model uses a current density of cation intercalation as a variable without use of a current density of solid electrolyte interphase formation as a variable; and (d) determining a predicted end of life of the electrochemical cell based on one of the calculated cell capacities being less than a predetermined percentage of the nominal capacity.

In another aspect, the disclosure provides a method for predicting an end of life of an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles. The method comprises: (a) selecting at least one cell component selected from the group consisting of electrolytes, cathode active materials, and anode active materials, the at least one cell component causing the degradation of the cell; (b) determining a nominal discharge capacity for the cell at a state of health of 100%; (c) sequentially calculating a cell capacity at an end of each of the plurality of cell cycles based on total cyclable cations (ηₛ), accessible storage sites in each electrode, and the at least one cell component using a degradation model based on porous-electrode theory and having one or more degradation pathways, wherein the model uses a current density of cation intercalation as a variable without use of a current density of cation plating as a variable; and (d) determining a predicted end of life of the electrochemical cell based on one of the calculated cell capacities being less than a predetermined percentage of the nominal capacity.

In one version of any of these methods for predicting an end of life of an electrochemical cell, the model does not include an algebraic equation. In one version of any of these methods for predicting an end of life of an electrochemical cell, sequentially calculating the cell capacity at the end of each of the plurality of cell cycles is at least three times faster than a degradation model based on porous-electrode theory that includes an algebraic equation.

In one version of any of these methods for predicting an end of life of an electrochemical cell, the model does not include an algebraic equation for calculating a surface potential difference (Φ_{s,n}−Φₑ) where Φ_{s,n} denotes a potential of a solid phase of the anode, and Φₑ denotes a potential of a phase of the electrolyte.

In one version of any of these methods for predicting an end of life of an electrochemical cell, step (c) comprises sequentially calculating the cell capacity at the end of each of the plurality of cell cycles based on a solid electrolyte interphase kinetic rate constant (k_{SEI}), a solid electrolyte interphase layer diffusivity (D_{SEI}), and an active material particle cracking rate (β_{LAM}). Step (c) can comprise tuning the solid electrolyte interphase kinetic rate constant, the solid electrolyte interphase layer diffusivity, and the active material particle cracking rate to create a linear degradation path for the calculated cell capacities of the plurality of cell cycles. Step (c) can comprise tuning the solid electrolyte interphase kinetic rate constant, the solid electrolyte interphase layer diffusivity, and the active material particle cracking rate to create a self-limiting degradation path for the calculated cell capacities of the plurality of cell cycles. Step (c) can comprise tuning the solid electrolyte interphase kinetic rate constant, the solid electrolyte interphase layer diffusivity, and the active material particle cracking rate to create an accelerating degradation path for the calculated cell capacities of the plurality of cell cycles.

In one version of any of these methods for predicting an end of life of an electrochemical cell, calculating the cell capacity employs the relationship:

cell capacity=Cₙ(Θₙ¹⁰⁰−Θₙ⁰),

where Cₙ denotes a capacity of the anode, Θₙ¹⁰⁰ denotes a scaled volumed-averaged negative particle concentration at 100% State of Charge, and Θₙ⁰ denotes a scaled volumed-averaged negative particle concentration at 0% State of Charge.

In one version of any of these methods for predicting an end of life of an electrochemical cell, step (c) comprises sequentially calculating the cell capacity at the end of at least a portion of the plurality of cell cycles based on the total cyclable cations, a solid electrolyte interphase thickness (δ_{SEI}), a porosity (ε_{s,n}) of a solid phase of the anode, and a porosity (ε_{s,p}) of a solid phase of the cathode.

In one version of any of these methods for predicting an end of life of an electrochemical cell, the model does not include an algebraic equation for calculating a surface potential difference (Φ_{s,n}−Φₑ) where Φ_{s,n} denotes a potential of a solid phase of the anode, and Φₑ denotes a potential of a phase of the electrolyte.

In another aspect, the disclosure provides a method in a data processing system comprising at least one processor and at least one memory, the at least one memory comprising instructions executed by the at least one processor to implement an electrochemical cell end of life prediction system, wherein the electrochemical cell includes an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles. The method comprises: (a) receiving a selection of at least one cell component selected from the group consisting of electrolytes, cathode active materials, and anode active materials, the at least one cell component causing the degradation of the cell; (b) receiving a nominal discharge capacity for the cell at a state of health of 100%; (c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the cell cycles are initialized based on a rate of degradation over a plurality of previous cycles and wherein a time at which to simulate the next cycle is chosen based on the rate of degradation over the plurality of previous cycles; and (d) determining a predicted end of life of the electrochemical cell based on one of the calculated cell capacities being less than a predetermined percentage of the nominal capacity.

In another aspect, the disclosure provides a method in a data processing system comprising at least one processor and at least one memory, the at least one memory comprising instructions executed by the at least one processor to implement an electrochemical cell end of life prediction system, wherein the electrochemical cell includes an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles. The method comprises: (a) receiving a selection of at least one cell component selected from the group consisting of electrolytes, cathode active materials, and anode active materials, the at least one cell component causing the degradation of the cell; (b) receiving a nominal discharge capacity for the cell at a state of health of 100%; (c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the model uses a current density of cation intercalation as a variable without use of a current density of solid electrolyte interphase formation as a variable; and (d) determining a predicted end of life of the electrochemical cell based on one of the calculated cell capacities being less than a predetermined percentage of the nominal capacity.

In another aspect, the disclosure provides a method in a data processing system comprising at least one processor and at least one memory, the at least one memory comprising instructions executed by the at least one processor to implement an electrochemical cell end of life prediction system, wherein the electrochemical cell includes an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles. The method comprises: (a) receiving a selection of at least one cell component selected from the group consisting of electrolytes, cathode active materials, and anode active materials, the at least one cell component causing the degradation of the cell; (b) receiving a nominal discharge capacity for the cell at a state of health of 100%; (c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the model uses a current density of cation intercalation as a variable without use of a current density of cation plating as a variable; and (d) determining a predicted end of life of the electrochemical cell based on one of the calculated cell capacities being less than a predetermined percentage of the nominal capacity.

In one version of any of these methods in a data processing system, the model does not include an algebraic equation. In one version of any of these methods in a data processing system, sequentially calculating the cell capacity at the end of each of the plurality of cell cycles is at least three times faster than a degradation model based on porous-electrode theory that includes an algebraic equation.

In one version of any of these methods in a data processing system, the model does not include an algebraic equation for calculating a surface potential difference (Φ_{s,n}−Φₑ) where Φ_{s,n} denotes a potential of a solid phase of the anode, and Φₑ denotes a potential of a phase of the electrolyte.

In one version of any of these methods in a data processing system, step (c) comprises sequentially calculating the cell capacity at the end of each of the plurality of cell cycles based on a solid electrolyte interphase kinetic rate constant (k_{SEI}), a solid electrolyte interphase layer diffusivity (D_{SEI}), and an active material particle cracking rate (β_{LAM}). Step (c) can comprise tuning the solid electrolyte interphase kinetic rate constant, the solid electrolyte interphase layer diffusivity, and the active material particle cracking rate to create a linear degradation path for the calculated cell capacities of the plurality of cell cycles. Step (c) can comprise tuning the solid electrolyte interphase kinetic rate constant, the solid electrolyte interphase layer diffusivity, and the active material particle cracking rate to create a self-limiting degradation path for the calculated cell capacities of the plurality of cell cycles. Step (c) can comprise tuning the solid electrolyte interphase kinetic rate constant, the solid electrolyte interphase layer diffusivity, and the active material particle cracking rate to create an accelerating degradation path for the calculated cell capacities of the plurality of cell cycles.

In one version of any of these methods in a data processing system, calculating the cell capacity employs the relationship:

cell capacity=Cₙ(Θₙ¹⁰⁰−Θₙ⁰),

where Cₙ denotes a capacity of the anode, Θₙ¹⁰⁰ denotes a scaled volumed-averaged negative particle concentration at 100% State of Charge, and Θₙ⁰ denotes a scaled volumed-averaged negative particle concentration at 0% State of Charge.

In one version of any of these methods in a data processing system, step (c) comprises sequentially calculating the cell capacity at the end of at least a portion of the plurality of cell cycles based on the total cyclable cations, a solid electrolyte interphase thickness (δ_{SEI}), a porosity (ε_{s,n}) of a solid phase of the anode, and a porosity (ε_{s,p}) of a solid phase of the cathode.

In one version of any of these methods in a data processing system, the model does not include an algebraic equation for calculating a surface potential difference (Φ_{s,n}−Φₑ) where Φ_{s,n} denotes a potential of a solid phase of the anode, and Φₑ denotes a potential of a phase of the electrolyte.

These and other features, aspects, and advantages of the present invention will become better understood upon consideration of the following detailed description, drawings, and appended claims.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a schematic of a lithium ion battery.

FIG. 1A is a schematic of a lithium metal battery.

FIG. 1B shows the schematics of a multiparticle electrochemical and mechanical model of a lithium ion battery.

FIG. 1C shows linear, self-limiting, and accelerating capacity fade trajectories versus cycle number with the parameters in Table 3.

FIG. 2 shows comparisons of ODE (ordinary differential equation) formulation (8) and DAE (differential algebraic equation) formulation (1c)-(1g) for SEI (solid electrolyte interphase) equations. Both formulations are simulated using PyBaMM [Ref. 27].

FIG. 3 shows root mean square percentage error between the ODE formulation (8) and DAE formulation (1c)-(1g) for the SEI equations.

FIG. 4 shows a schematic of an inter-cycle extrapolation algorithm. The change in SOH parameters over one cycle, Δy₁, is assumed to be constant for the next n cycles, resulting in a nΔy₁ change over n cycles. The change in SOH over the nth cycle is then calculated and extrapolated to the 2n^{th} cycle, etc. Here SOH represents an internal degradation variable of the model, of which there can be several, for example SEI thickness (δ_{SEI}) or active material volume fraction in either electrode (ε_{s,k}).

FIG. 5 shows extrapolating the change from xo (red line) to x_{end} (blue line) by n steps leads to an extrapolated value (black line) that is outside of the physical range [0,1] for the dimensionless particle concentration. Therefore, the next cycle cannot be simulated starting from the extrapolated concentration. Here, n=30.

FIG. 6 shows a comparison of the full simulation to the fixed-step extrapolation algorithm. The fixed-step extrapolation algorithm is accurate in the linear and accelerating cases, where the underlying degradation modes are linear (see below). In the self-limiting case, where degradation is nonlinear, there is significant error from fixed-step extrapolation, with larger error for larger steps.

FIG. 7 shows change in degradation variables during linear degradation. The degradation modes ‘loss of lithium inventory’ (LLI) and ‘loss of active material’ (LAM) are defined below. The stoichiometry limits are the envelope of the electrode stoichiometry during cycling, which also changes as the battery degrade.

FIG. 8 shows change in degradation variables during self-limiting degradation (see FIG. 7 for details).

FIG. 9 shows change in degradation variables during accelerating degradation (see FIG. 7 for details).

### DETAILED DESCRIPTION OF THE INVENTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items.

The following discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown and described, but are to be accorded the widest scope consistent with the principles and features disclosed herein. Skilled artisans will recognize the examples provided herein have many useful alternatives and fall within the scope of embodiments of the invention.

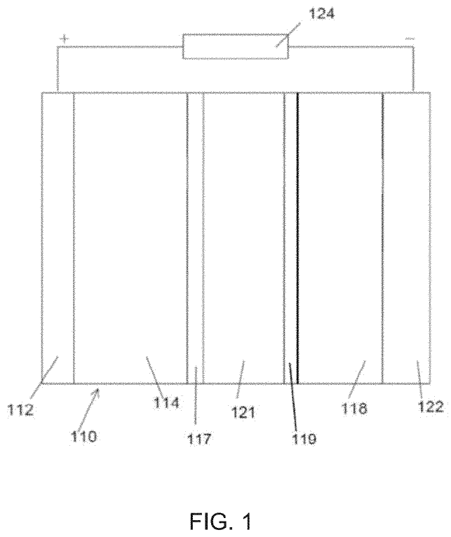

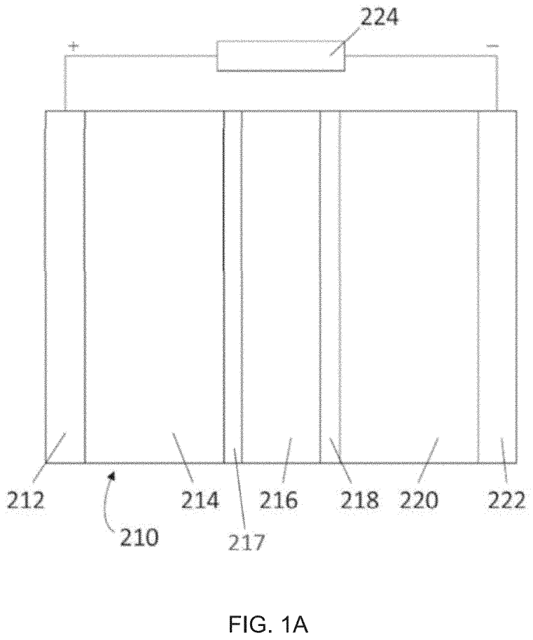

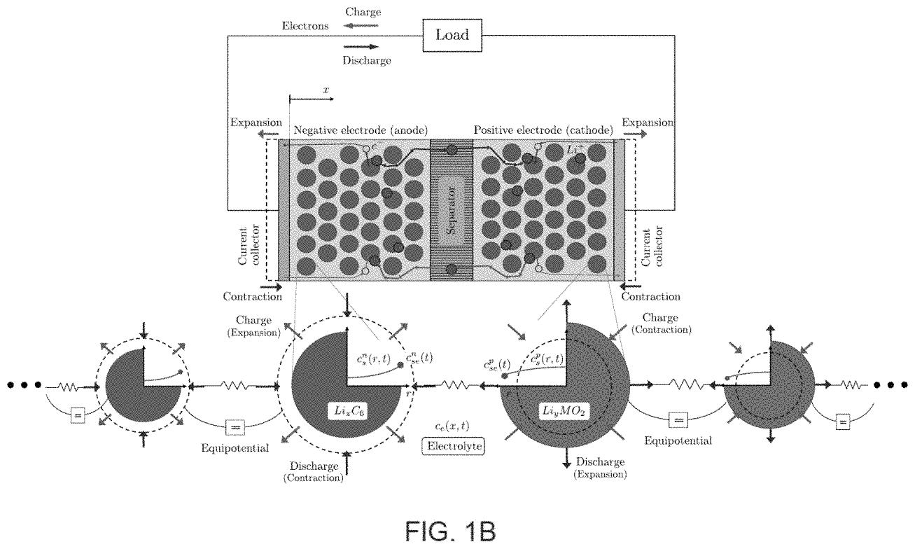

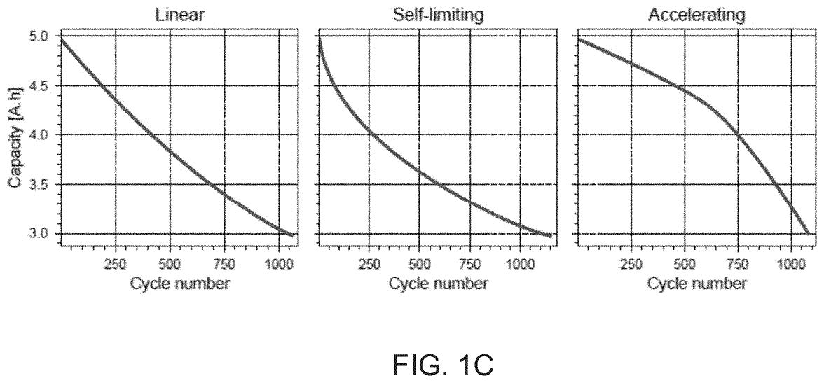

FIG. 1 shows a non-limiting example of a lithium ion battery 110 that may be manufactured according to one embodiment of the present disclosure. The lithium ion battery 110 includes a first current collector 112 (e.g., aluminum) in contact with a cathode 114. A solid state electrolyte 121 is arranged between a solid electrolyte interphase 117 on the cathode 114 and a solid electrolyte interphase 119 on an anode 118, which is in contact with a second current collector 122 (e.g., aluminum). A solid electrolyte interphase may also be within a porous structure of the cathode 114, and a solid electrolyte interphase may also be within a porous structure of the anode 118. The first and second current collectors 112 and 122 of the lithium ion battery 110 may be in electrical communication with an electrical component 124. The electrical component 124 could place the lithium ion battery 110 in electrical communication with an electrical load that discharges the battery or a charger that charges the battery.

A suitable active material for the cathode 114 of the lithium ion battery 110 is a lithium host material capable of storing and subsequently releasing lithium ions. An example cathode active material is a lithium metal oxide wherein the metal is one or more aluminum, cobalt, iron, manganese, nickel and vanadium. Non-limiting example lithium metal oxides are LiCoO₂ (LCO), LiFeO₂, LiMnO₂ (LMO), LiMn₂O₄, LiNiO₂ (LNO), LiNiₓCo_{y}O₂, LiMnₓCo_{y}O₂, LiMnₓNi_{y}O₂, LiMnₓNi_{y}O₄, LiNiₓCo_{y}Al_{z}O₂ (NCA), LiNi_{1/3}Mn_{1/3}Co_{1/3}O₂ and others. Another example of cathode active materials is a lithium-containing phosphate having a general formula LiMPO₄ wherein M is one or more of cobalt, iron, manganese, and nickel, such as lithium iron phosphate (LFP) and lithium iron fluorophosphates. The cathode can comprise a cathode active material having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811). The cathode active material can be a mixture of any number of these cathode active materials.

In some aspects, the cathode 114 may include a conductive additive. Many different conductive additives, e.g., Co, Mn, Ni, Cr, Al, or Li, may be substituted or additionally added into the structure to influence electronic conductivity, ordering of the layer, stability on delithiation and cycling performance of the cathode materials. Other suitable conductive additives include graphite, carbon black, acetylene black, Ketjen black, channel black, furnace black, lamp black, thermal black, conductive fibers, metallic powders, conductive whiskers, conductive metal oxides, and mixtures thereof.

A suitable active material for the anode 118 of the lithium ion battery 110 is a lithium host material capable of incorporating and subsequently releasing the lithium ion such as graphite (artificial, natural), a lithium metal oxide (e.g., lithium titanium oxide), hard carbon, a tin/cobalt alloy, or silicon/carbon. The anode active material can be a mixture of any number of these anode active materials. In some embodiments, the anode 118 may also include one or more conductive additives similar to those listed above for the cathode 114.

A suitable solid state electrolyte 121 of the lithium ion battery 110 includes an electrolyte material having the formula LiᵤReᵥM_{w}AₓO_{y}, wherein
Re can be any combination of elements with a nominal valance of +3 including La, Nd, Pr, Pm, Sm, Sc, Eu, Gd, Tb, Dy, Y, Ho, Er, Tm, Yb, and Lu;
M can be any combination of metals with a nominal valance of +3, +4, +5 or +6 including Zr, Ta, Nb, Sb, W, Hf, Sn, Ti, V, Bi, Ge, and Si;
A can be any combination of dopant atoms with nominal valance of +1, +2, +3 or +4 including H, Na, K, Rb, Cs, Ba, Sr, Ca, Mg, Fe, Co, Ni, Cu, Zn, Ga, Al, B, and Mn;
u can vary from 3-7.5;
v can vary from 0-3;
w can vary from 0-2;
x can vary from 0-2; and
y can vary from 11-12.5.
   The electrolyte material may be an undoped or doped lithium lanthanum zirconium oxide.

Another example solid state electrolyte 121 can include any combination oxide or phosphate materials with a garnet, perovskite, NaSICON, or LiSICON phase. The solid state electrolyte 121 of the lithium ion battery 110 can include any solid-like material capable of storing and transporting ions between the anode 118 and the cathode 114.

The current collector 112 and the current collector 122 can comprise a conductive material. For example, the current collector 112 and the current collector 122 may comprise molybdenum, aluminum, nickel, copper, combinations and alloys thereof or stainless steel.

Alternatively, a separator may replace the solid state electrolyte 121, and the electrolyte for the battery 110 may be a liquid electrolyte. An example separator material for the battery 110 can a permeable polymer such as a polyolefin. Example polyolefins include polyethylene, polypropylene, and combinations thereof. The liquid electrolyte may comprise a lithium compound in an organic solvent. The lithium compound may be selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf). The organic solvent may be selected from carbonate based solvents, ether based solvents, ionic liquids, and mixtures thereof. The carbonate based solvent may be selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate; and the ether based solvent is selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane.

The solid electrolyte interphases 117, 119 form during a first charge of the lithium ion battery 110. To further describe the formation of a solid electrolyte interphase, a non-limiting example lithium ion battery 110 using a liquid electrolyte and having an anode comprising graphite is used in this paragraph. As lithiated carbons are not stable in air, the non-limiting example lithium ion battery 110 is assembled in its discharged state that means with a graphite anode and lithiated positive cathode materials. The electrolyte solution is thermodynamically unstable at low and very high potentials vs. Li/Li⁺. Therefore, on first charge of the lithium ion battery cell, the electrolyte solution begins to reduce/degrade on the graphite anode surface and forms the solid electrolyte interphase (SEI). There are competing and parallel solvent and salt reduction processes, which result in deposition of a number of organic and inorganic decomposition products on the surface of the graphite anode. The SEI layer imparts kinetic stability to the electrolyte against further reductions in the successive cycles and thereby ensures good cyclability of the electrode. It has been reported that SEI thickness may vary from few angstroms to tens or hundreds of angstroms. Studies suggest the SEI on a graphitic anode to be a dense layer of inorganic components close to the carbon of the anode, followed by a porous organic or polymeric layer close to the electrolyte phase.

The present invention is not limited to lithium ion batteries. In alternative embodiments, a suitable anode can comprise magnesium, sodium, or zinc. Suitable alternative cathode and electrolyte materials can be selected for such magnesium ion batteries, sodium ion batteries, or zinc ion batteries. For example, a sodium ion battery can include: (i) an anode comprising sodium ions, (ii) a solid state electrolyte comprising a metal cation-alumina (e.g., sodium-β-alumina or sodium-β″-alumina), and (iii) a cathode comprising an active material selected from the group consisting of layered metal oxides, (e.g., NaFeO, NaMnO, NaTiO, NaNiO, NaCrO, NaCoO, and NaVO) metal halides, polyanionic compounds, porous carbon, and sulfur containing materials.

FIG. 1A shows a non-limiting example of a lithium metal battery 210 that may be manufactured according to one embodiment of the present disclosure. The lithium metal battery 210 includes a current collector 212 in contact with a cathode 214. A solid state electrolyte 216 is arranged between a solid electrolyte interphase 217 on the cathode 214 and a solid electrolyte interphase 218 on an anode 220, which is in contact with a second current collector 222 (e.g., aluminum). The current collectors 212 and 222 of the lithium metal battery 210 may be in electrical communication with an electrical component 224. The electrical component 224 could place the lithium metal battery 210 in electrical communication with an electrical load that discharges the battery or a charger that charges the battery. A suitable active material for the cathode 214 of the lithium metal battery 210 is one or more of the lithium host materials listed above for battery 110, or porous carbon (for a lithium air battery), or a sulfur containing material (for a lithium sulfur battery). A suitable solid state electrolyte material for the solid state electrolyte 216 of the lithium metal battery 210 is one or more of the solid state electrolyte materials listed above for battery 110. In one embodiment, the anode 220 of the lithium metal battery 210 comprises lithium metal. In one embodiment, the anode 220 of the lithium metal battery 210 consists essentially of lithium metal.

Alternatively, a separator may replace the solid state electrolyte 216, and the electrolyte for the lithium metal battery 210 may be a liquid electrolyte. An example separator material for the lithium metal battery 210 is one or more of the separator materials listed above for lithium ion battery 110. A suitable liquid electrolyte for the lithium metal battery 210 is one or more of the liquid electrolytes listed above for lithium ion battery 110.

The solid electrolyte interphases 217, 218 form during a first charge of the lithium metal battery 210. To further describe the formation of a solid electrolyte interphase, a non-limiting example lithium metal battery 210 using a liquid electrolyte and having a lithium metal anode is used in this paragraph. The liquid electrolyte comprises a lithium salt in an organic solvent. The non-limiting example lithium metal battery 210 is assembled in its discharged state which means with a lithium metal anode and lithiated positive cathode materials. The reduction potential of the organic solvent is typically below 1.0 V (vs. Li⁺/Li). Therefore, when the bare lithium anode is exposed to the electrolyte solution and a first charging current is applied, immediate reactions between lithium and electrolyte species are carried out. The insoluble products of the parasitic reactions between lithium ions, anions, and solvents depositing on the metallic lithium anode surface are regarded as the solid electrolyte interphase. As the SEI components strongly depend on the electrode material, electrolyte salts, solvents, as well as the working state of cell, no identical SEI layer can be found in two different situations. Consequently, the actual surface chemistry of SEI layer in a given system is typically obtained by characterization methods such as Fourier transform infrared spectroscopy (FTIR) and X-ray photoelectron spectroscopy (XPS).

The present invention is not limited to lithium metal batteries. In alternative embodiments, a suitable anode can comprise magnesium metal, sodium metal, or zinc metal. Suitable alternative cathode and electrolyte materials can be selected for such magnesium metal batteries, sodium metal batteries, or zinc metal batteries.

In one embodiment of the invention, there is provided a method for manufacturing an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles. The method includes the steps of: (a) selecting at least one cell component selected from the group consisting of electrolytes, cathode active materials, and anode active materials wherein the at least one cell component causes the degradation of the cell; (b) determining a nominal discharge capacity for the cell at a state of health of 100%; (c) sequentially calculating a cell capacity at an end of each of the plurality of cell cycles based on total cyclable cations, accessible storage sites in each electrode, and the at least one cell component using a degradation model based on porous-electrode theory and having one or more degradation pathways; and determining a predicted end of life of the electrochemical cell based on one of the calculated cell capacities being less than a predetermined percentage of the nominal capacity. For example, end-of-life can be defined as a 20% degradation from nominal capacity.

In one version of this method, the cell cycles are initialized based on a rate of degradation over a plurality of previous cycles and wherein a time at which to simulate the next cycle is chosen based on the rate of degradation over the plurality of previous cycles. In another version of this method, the model uses a current density of cation intercalation as a variable without use of a current density of solid electrolyte interphase formation as a variable. In another version of this method, the model uses a current density of cation intercalation as a variable without use of a current density of cation plating as a variable. Another version of this method includes the steps of: (e) selecting a different at least one cell component; (f) sequentially calculating a second cell capacity at an end of each of the plurality of cell cycles based on the different at least one cell component; (g) determining an additional predicted end of life of the electrochemical cell based on one of the calculated second cell capacities being less than the predetermined percentage of the nominal capacity; (h) comparing the predicted end of life and the additional predicted end of life and selecting a preferred cell having a greater predicted end of life of the predicted end of life and the additional predicted end of life; and (i) manufacturing the preferred cell.

In another embodiment of the invention, there is provided a method for predicting an end of life of an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles. The method includes the steps of: (a) selecting at least one cell component selected from the group consisting of electrolytes, cathode active materials, and anode active materials, the at least one cell component causing the degradation of the cell; (b) determining a nominal discharge capacity for the cell at a state of health of 100%; (c) sequentially calculating a cell capacity at an end of each of the plurality of cell cycles based on total cyclable cations, accessible storage sites in each electrode, and the at least one cell component using a degradation model based on porous-electrode theory and having one or more degradation pathways; and (d) determining a predicted end of life of the electrochemical cell based on one of the calculated cell capacities being less than a predetermined percentage of the nominal capacity.

In one version of this method, the cell cycles are initialized based on a rate of degradation over a plurality of previous cycles and wherein a time at which to simulate the next cycle is chosen based on the rate of degradation over the plurality of previous cycles. In another version of this method, the model uses a current density of cation intercalation as a variable without use of a current density of solid electrolyte interphase formation as a variable. In another version of this method, the model uses a current density of cation intercalation as a variable without use of a current density of cation plating as a variable.

In another embodiment of the invention, there is provided a method in a data processing system comprising at least one processor and at least one memory, the at least one memory comprising instructions executed by the at least one processor to implement an electrochemical cell end of life prediction system, wherein the electrochemical cell includes an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles. The method includes the steps of: (a) receiving a selection of at least one cell component selected from the group consisting of electrolytes, cathode active materials, and anode active materials, the at least one cell component causing the degradation of the cell; (b) receiving a nominal discharge capacity for the cell at a state of health of 100%; (c) sequentially calculating a cell capacity at an end of each of the plurality of cell cycles based on total cyclable cations, accessible storage sites in each electrode, and the at least one cell component using a degradation model based on porous-electrode theory and having one or more degradation pathways; and (d) determining a predicted end of life of the electrochemical cell based on one of the calculated cell capacities being less than a predetermined percentage of the nominal capacity.

In one version of this method, the cell cycles are initialized based on a rate of degradation over a plurality of previous cycles and wherein a time at which to simulate the next cycle is chosen based on the rate of degradation over the plurality of previous cycles. In another version of this method, the model uses a current density of cation intercalation as a variable without use of a current density of solid electrolyte interphase formation as a variable. In another version of this method, the model uses a current density of cation intercalation as a variable without use of a current density of cation plating as a variable.

In this disclosure, we propose non-limiting example methods including an algorithm to speed up physics-based battery lifetime simulations by one to two orders of magnitude compared to the state-of-the-art. This algorithm makes use of the difference between the “fast” timescale of battery cycling and the “slow” timescale of battery degradation by adaptively selecting and simulating representative cycles, and hence requires fewer cycle simulations to simulate the entire lifetime. For example, simulations of three months of life that previously took three minutes can now be done in under five seconds. This enables interactions with the simulations on a human timescale, and therefore opens the possibility for much faster and more accurate model development, testing, and comparison with experimental data.

Some embodiments of the invention provide algorithms to speed up physics-based battery lifetime simulations by one to two orders of magnitude compared to the state-of-the-art. Some embodiments include a reformulation of the Single Particle Model with side reactions to remove algebraic equations and hence reduce stiffness, with 3× speed-up in simulation time (intra-cycle reformulation). Other embodiments of the invention provide an algorithm that makes use of the difference between the ‘fast’ timescale of battery cycling and the ‘slow’ timescale of battery degradation by adaptively selecting and simulating representative cycles, skipping other cycles, and hence requires fewer cycle simulations to simulate the entire lifetime (adaptive inter-cycle extrapolation). This algorithm is demonstrated with a specific degradation mechanism but can be applied to various models of aging phenomena. In a case study considered, simulations of the entire lifetime are performed in under 5 seconds. This opens the possibility for much faster and more accurate model development, testing, and comparison with experimental data.

### EXAMPLE

The following Example has been presented in order to further illustrate the invention and is not intended to limit the invention in any way. The statements provided in the Example are presented without being bound by theory.

### 1. Introduction to Example

In general, improved understanding of battery degradation can lead to better reliability, safety, extended utilization of batteries, and hence reduced costs [Ref. 1]. Batteries for light duty vehicles and grid applications are often made to last and warranted for 8-10 years [Refs. 2, 3]. Battery degradation could therefore take around 10 years in the field, which is prohibitively long for understanding the effect of a battery design parameter change on lifetime. The total testing time is often reduced in the lab by using accelerated aging conditions and skipping rest between cycles, degrading the battery in a few months. To reduce the time further, modeling is required. In particular, physics-based electrochemical models that embed degradation mechanisms are useful for evaluating the capacity and power fade of lithium-ion batteries under various duty cycles, and hence predicting their lifetime, since they can directly simulate a wide range of realistic battery uses at various scales [Ref. 4]. However, physics-based simulations of the entire battery lifetime typically take several minutes to hours. For example, if a simulation of one full charge/discharge cycle takes one second, simulating 1000 cycles would take around 15 minutes. This is much faster than experimental timescales, but still too slow and not ideal for rapid feedback and repeated simulations of the model, for example in a parameter estimation routine which require multiple forward solves of the model. In this Example, we propose an algorithm to speed up physics-based battery lifetime simulations by one to two orders of magnitude, and hence simulate the entire lifetime of a battery in just a few seconds (Table 1).

TABLE 1

| | One full equivalent cycle | | Lifetime | |
|---|---|---|---|---|
| Battery lifetime | 1 | week | 8-10 | years |
| Lab experiments | 2 | hours | 3 | months |
| Standard SPM | 0.6 | seconds | 10 | minutes |
| SPM with intra-cycle | 0.2 | seconds | 3 | minutes |
| reformulation | | | | |
| Reformulated SPM with | 0.2 | seconds | 5 | seconds |
| adaptive inter-cycle | | | | |
| extrapolation | | | | |

Table 1 includes order-of-magnitude timescales required to measure or simulate a single cycle or the entire lifetime of a battery. A typical driving pattern and industry standard for an eight-year warranty can be assumed. This can be reduced by continuously cycling the cell in the lab, and further reduced using simulations. For example, simulating one full cycle of the Single Particle Model (SPM) takes 0.6 seconds, so simulating the full lifetime (1000 cycles) takes around 10 minutes. This can be reduced to 0.2 seconds/3 minutes by reformulating the model to eliminate an algebraic equation (intra-cycle reformulation, see below). Without further changing the simulation time for one cycle, the lifetime simulation time can be further reduced to under 5 seconds by adaptively extrapolating between cycles (inter-cycle extrapolation, see below).

Many modeling studies investigate the degradation for a single cycle, and there have been significant advances in performing simulations of individual cycles (intra-cycle simulations) as efficiently as possible. Smith et al. proposed a low order dynamic model with applications in battery management [Ref. 5]. Cai et al. derived a reduced-order model using proper orthogonal decomposition [Ref. 6]. Northrop et al. reformulated the model for implementation in a battery management system [Ref. 7], based on earlier work by Subramanian et al. [Ref. 8]. Barai et al. proposed a reduced order model for mechanical degradation [Ref. 9]. Two other reduced-order models are the Single Particle Model [Ref. 10] and Single Particle Model with electrolyte [Ref. 11]. Various authors have used perturbation theory to derive reduced-order one-dimensional [Refs. 12, 13, 14, 15, 16] and three-dimensional [Refs. 17, 18] models in a variety of asymptotic limits.

In comparison, few methods to accelerate simulations over the entire battery life have been proposed in the literature. The idea of using a detailed microscale simulation to inform a macroscale simulation without explicitly deriving the macroscale equations may exist [Ref. 19, 20]. More rigorously, systems with distinct timescales can be solved asymptotically using the method of multiple scales [Ref. 21]. Battery simulations are ideally suited to this approach, since they have a fast cycling timescale and a slow degradation timescale, and the fast timescale is usually periodic when performing controlled experiments in a laboratory setting [Ref. 1]. However, generally few studies have attempted to separate the cycling and degradation timescales.

One suggested methods include an algorithm to iteratively simulate one cycle and linearly extrapolate the degradation over a fixed number of cycles (inter-cycle extrapolation). This algorithm was proposed for fuel cell models by Mayur et al. [Refs. 22, 23] as the ‘time-upscaling method’, and adapted to lithium-ion batteries by Kupper et al. [Ref. 24]. Independently, Vora et al. [Ref. 25] proposed a similar algorithm and called it ‘extrapolation’. This fixed-size linear extrapolation algorithm has two major downsides, and has not gained wide-spread traction so far. First, the ‘extrapolation’ hyper-parameter needs to be selected a priori, with no systematic way of knowing an appropriate value. Second, the method takes fixed steps over the entire battery life, but some regions may require smaller steps and others larger steps depending on the linearity of aging.

Some embodiments of the invention provide an adaptive inter-cycle extrapolation algorithm where the step size is chosen automatically based on the past and present degradation rates. This algorithm works with any degradation model based on porous-electrode theory, but for presentation purposes a Single Particle Model with SEI growth and particle cracking, introduced in the Example below, can be used. Different degradation parameters can be used to simulate different capacity fade trajectories (linear, self-limiting, and accelerating). Shown below, the intra-cycle model can be reformulated to eliminate algebraic equations, for a 3× speed-up at almost no loss of accuracy. Also described below is the adaptive inter-cycle extrapolation algorithm, and results in each of the three degradation cases. In each, a further one to two order of magnitude speed-ups compared to the baseline is achieved. Since the speed-up combines multiplicatively with speed-ups in simulation of a single cycle, the entire lifetime of the battery can be advantageously simulated in just a few seconds.

This enables interactions with the simulations on a human timescale [Ref. 26], and therefore opens the possibility for much faster and more accurate model development and comparison with experimental data. The algorithm is implemented in the open-source battery modeling package PyBaMM [Ref. 27] and thus can easily be used to simulate any aging model implemented within that framework. Alternatively, it can easily be incorporated in other simulation frameworks. The results presented below also demonstrate how the capacity fade curve changes qualitatively when different degradation mechanisms dominate, as FIG. 1C. In particular, we investigate the knee point around cycle 600 in the ‘accelerating’ capacity fade curve, and show that this knee point is caused by electrode saturation. Finally, several extensions and possible research directions enabled by this algorithm are discussed below.

### 2. Degradation Model

The algorithms introduced herein are intended to be general and work with any degradation model based on porous-electrode theory. For demonstration purposes, the numerical improvements in a case study degradation model are discussed herein, namely the Single Particle Model with SEI formation [Ref. 28] and loss of active material [Refs. 29, 30] due to particle swelling [Refs. 31, 32]. FIG. 1B shows the schematics of a multiparticle electrochemical and mechanical model of a lithium ion battery [Ref. 32]. More complicated models can also be used without modification to the algorithms that are introduced below. The case study degradation model is as follows:

### Single Particle Model:

$$\frac{\partial {c}_{s , k}}{\partial t} = \frac{1}{{r}^{2}} \frac{\partial }{\partial r} ( {r}^{2} \frac{\partial {c}_{s , k}}{\partial r} ) , 0 < r < {R}_{k} , \qquad ( 1 a )$$

$$\frac{\partial {c}_{s , k}}{\partial r} = \frac{{j}_{int} , k}{F} , r = {R}_{k} . \qquad ( 1 b )$$

SEI model [Ref. 28]:

$$j \text{?} = 2 {i}_{0} sinh ( \frac{F {η}_{k}}{2 RT} ) , \qquad ( 1 c )$$

$${j}_{SEI} = {f}_{SEI} ( {η}_{SEI} , {δ}_{SEI} ) , \qquad ( 1 d )$$

$$\frac{I}{{a}_{s , n} {L}_{n}} = {j}_{tot , n} = {j}_{int , n} + {j}_{SEI} , \qquad ( 1 e )$$

$${η}_{n} = {ϕ}_{s , n} - {ϕ}_{e} - {U}_{n} ( {c}_{s , n}^{surf} ) - {j}_{tot , n} R \text{?} {δ}_{SEI} , \qquad ( 1 f )$$

$${η}_{SEI} = {ϕ}_{s , n} - {ϕ}_{e} - {U}_{SEI} - {j}_{tot , k} R \text{?} {δ}_{SEI} , \qquad ( 1 g )$$

$$\frac{d {δ}_{SEI}}{dt} = {\hat{V}}_{SEI} \frac{{a}_{s , n} {j}_{SEI}}{2 F} , \qquad ( 1 h )$$

$${η}_{p} = {ϕ}_{s , p} - {ϕ}_{e} - {U}_{p} ( {c}_{s , p}^{surf} ) , \qquad ( 1 i )$$

$$- \frac{I}{{a}_{s , p} {L}_{p}} = {j}_{tot , p} = {j}_{int , p} , \qquad ( 1 j )$$

$$\text{?} \text{indicates text missing or illegible when filed}$$

where f_{SEI} is a function derived below. Particle mechanics, assuming maximum stress at the particle surface and zero minimum stress [Refs. 29, 30, 31, 32]:

$${σ}_{h , k} = \frac{2 {Ω}_{k} {E}_{k}}{3 ( 1 - {v}_{k} )} ( \frac{1}{{R}_{k}^{3}} {\int }_{0}^{{R}_{k}} {c}_{s , k} {r}^{2} dr - {c}_{s , k}^{surf} ) , \qquad ( 1 k )$$

$$\frac{d {ϵ}_{s , k}}{dt} = {{β}_{LAM} ( \frac{{σ}_{h , k}}{{σ}_{k}^{critical}} )}^{{m}_{LAM}} , \qquad ( 1 l )$$

$${a}_{s , k} = \frac{3 {ε}_{s , k}}{{R}_{k}} , \qquad ( 1 m )$$

### Voltage:

V=Uₚ(c_{s,p}^{surf})−Uₙ(c_{s,n}^{surf})+ηₚ−ηₙ. (1n)

Parameter values are as in [Ref. 32] with additional degradation parameters given in Table 2. After spatial discretization (for example using finite volumes), the discretized state vector is:

x=[c_{s,n},c_{s,p},δ_{SEI},ε_{s,n},ε_{s,p}]^{T}. (2)

The degradation rate can be controlled by tuning three parameters k_{SEI}, D_{SEI}, and β_{LAM}. The fast simulation algorithm is demonstrated in three scenarios with qualitatively different degradation paths: one linear, one self-limiting, and one accelerating (see FIG. 1C). The parameters that result in these three behaviors are given in Table 3. In each case, the entire lifetime is simulated using both standard sequential cycle simulations and adaptive inter-cycle extrapolation, and compare the results. Each cycle consists of a 1 C discharge until 3 V, followed by 1 hour rest, then 1 C charge until 4.2 V, and finally 4.2 V hold until the current goes below C/50. Simulations are performed until 60% capacity fade, with capacity defined by equation (26) derived below. The capacity fade curves in FIG. 1C are obtained by solving the model (1) in PyBaMM [Ref. 27], using the Method of Lines to semi-discretize the PDEs and SUNDIALS (via CasADi) [Refs. 33, 34] to solve the resulting system of ODEs/DAEs. Each cycle is simply initialized with the final state of the previous cycle,

TABLE 2

| | | Value | | |
|---|---|---|---|---|
| Parameter | Meaning | neg | pos | Ref. |
| c_{EC}⁰ | Concentration of EC in bulk | 4541 | — | [35] |
| | electrolyte [mol/m³] | | | |
| V̅_{SEI} | SEI Molar volume [m³/mol] | 9.585 × 10⁻⁵ | — | [35] |
| α_{SEI} | SEI charge transfer coefficient [—] | 0.5 | — | [35] |
| δ_{SEI}⁰ | Initial SEI thickness [m] | 5 × 10⁻⁹ | — | [35] |
| R_{SEI} | SEI resistivity [Ωm] | 2 × 10⁵ | — | [35] |
| Eₖ | Young's modulus [Pa] | 15 × 10⁹ | 375 × 10⁹ | [35] |
| υₖ | Poisson ratio [—] | 0.2 | 0.3 | [35] |
| Ωₖ | Partial molar volume of solute | 3.1 × 10⁻⁶ | −7.28 × 10⁻⁷ | [35] |
| | [m³/mol] | | | |
| σₖ^{critical} | Critical stress [Pa] | 60 × 10⁶ | 375 × 10⁶ | (†) |
| m_{LAM} | LAM exponent [—] | 2 | 2 | (†) |

Table 2 shows degradation parameters of the model. Other parameters are as in [Ref. 32]. The three remaining degradation parameters are different for each case as shown in Table 3. (†)=parameter introduced herein.

TABLE 3

| Parameter | Meaning | Linear | Self-limiting | Accelerating |
|---|---|---|---|---|
| k_{SEI} | SEI Kinetic rate constant [m/s] | 1 × 10⁻¹⁵ | 1 × 10⁻¹⁴ | 1 × 10⁻¹⁷ |
| D_{SEI} | SEI layer diffusivity [m2/s] | 2 × 10⁻¹⁶ | 5 × 10⁻²⁰ | 2 × 10⁻¹⁸ |
| β_{LAM} | Cracking rate [1/s] | 6 × 10⁻⁴ | 5 × 10⁻⁵ | 7 × 10⁻³ |

Table 3 shows key degradation parameters for each type of degradation. Parameters were selected to show the required capacity fade trajectory with 60% capacity fade in around 1000 cycles.

### 3. Intra-Cycle Model Reformulation of Side Reactions

One way to accelerate lifetime simulations is to make the simulation of individual cycles faster, either through model reformulation, reduced-order models, or more efficient numerical algorithms. Here, we propose a model reformulation for side reactions that can eliminate an algebraic equation from the model, and achieves a 3× speed-up compared to the original model. After spatial discretization, the reformulated model is an ODE system (instead of a DAE system for the original model), which enables the use of a wider range of algorithms from control theory.

Equations (1c)-(1g) can be collapsed into a single algebraic equation for the surface potential difference ϕ_{s,n}−ϕₑ,

$$\frac{I}{{a}_{n} {L}_{n}} = 2 {i}_{0} sinh ( \frac{F}{2 RT} ( {ϕ}_{s , n} - {ϕ}_{e} - {U}_{n} ( {c}_{s , n}^{surf} ) - {j}_{tot , n} R \text{?} {δ}_{SEI} ) ) - {f}_{SEI} ( {ϕ}_{s , n} - {ϕ}_{e} - {U}_{SEI} - {j}_{tot , k} R \text{?} {δ}_{SEI} {δ}_{SEI} ) . \qquad ( 4 )$$

$$\text{?} \text{indicates text missing or illegible when filed}$$

Without side reactions, and assuming symmetric Butler-Volmer as is usually the case, the potentials can then be found in closed form by inverting the Butler-Volmer equation. When side reactions are included, no closed form solutions exist for the transcendental equations of the form (4), and so (4) is an additional algebraic equation that must be solved alongside the other equations of the model (diffusion in the particles, in the case of the SPM). This turns the model from an ODE system to a DAE system after semi-discretization, and hence requires more complex and slower numerical methods to solve.

To avoid this issue, the model can be reformulated by exploiting the fact that the side reaction current density is much smaller than the intercalation current density [Ref. 29]. Systematically performing the asymptotic expansion requires a full non-dimensionalization, but the general idea is as follows. In some embodiments, we note that the size of the SEI current is much smaller than the size of the intercalation current and define some small parameter ε<<1 such that j_{SEI}/jᵢₙₜ σ(ε). We also define g_{SEI}=f_{SEI}/ε to be σ(1). We then expand kinetics variables in powers of ε.

jᵢₙ=jᵢₙₜ⁰+εjᵢₙₜ¹+ (5a)

j_{SEI}=j_{SEI}⁰+εj_{SEI}¹+, (5b)

η=η⁰+εη¹+, (5c)

η_{SEI}=η_{SEI}⁰+εη_{SEI}¹+ (5d)

Substituting (5) into 1c-1g, we find that to leading order in ε,

$${η}^{0} = \frac{2 RT}{F} {sinh}^{- 1} ( \frac{{j}_{int}^{0}}{2 {i}_{0}} ) , \qquad ( 6 a )$$

$${j}_{SEI}^{0} = 0 , \qquad \text{(6b)}$$

$${j}_{int}^{0} = {j}_{tot} . \qquad \text{(6c)}$$

To first order in ε,

j_{SEI}¹=g_{SEI}⁰=−f_{SEI}(η_{SEI}⁰,δ_{SEI})/ε, (7a)

jᵢₙₜ¹=−j_{SEI}¹, (7b)

and so we have an explicit approximate form for j,

jᵢₙₜ≈jᵢₙₜ⁰+εjᵢₙₜ¹=jₜₒₜ+f_{SEI}(η₀+U(cₛ)−U_{SEI},δ_{SEI}), (8)

where η⁰ is given by (6a). The explicit form (8) can be used in the boundary condition for the particle diffusion equation (28b), so that loss of lithium inventory during cycling is accounted for. With this approach, the model remains a system of ODEs; compared to the standard SPM, the only additional equation is equation (1h) for the SEI thickness growth, and there are no additional equations for the current. The derivation is very similar if other side reactions, such as lithium plating, are included. However, this approach breaks down if side reactions begin to dominate, since the asymptotic expansion is no longer valid.

It can be noted that the simplification from DAE to ODE only works if the Butler-Volmer reaction is symmetric, since it relies on inverting the sinh term. In the case of non-symmetric Butler-Volmer reactions, an alternative way to keep the model as an ODE system is to introduce capacitance into the system, for example in the form

$${C}_{dl} \frac{\partial }{\partial t} ( {ϕ}_{s} - {ϕ}_{e} ) = {j}_{tot} - {j}_{int} - {j}_{SEI} , \qquad ( 9 )$$

where C_{dl} is the double-layer capacitance [Refs. 36, 37].

Furthermore, the simplification from DAE to ODE is only applicable for electrode-averaged models such as the Single Particle Model. In the full Doyle-Fuller-Newman (DFN) model [Ref. 12], the total interfacial current jₜₒₜ is not simply given by (1e), but instead is spatially distributed in the electrode and must be solved for in an algebraic equation.

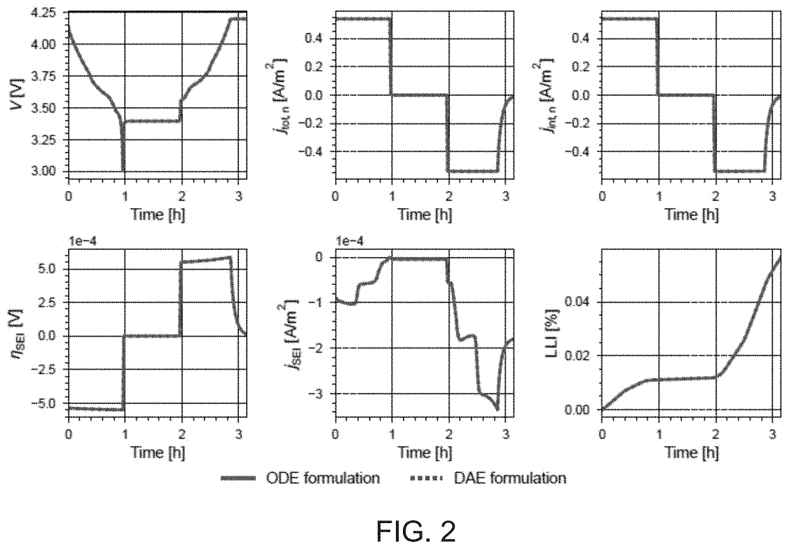

Described below is a comparison of the model with ODE formulation (8) and DAE formulation (1c)-(1g) for the SEI equations, over one representative 1 C/1 C discharge/charge cycle. The relevant electrical variables are compared in FIG. 2: voltage, V, total interfacial current density in the negative electrode, j_{tot,n}, intercalation current density in the negative electrode, j_{int,n}, SEI overpotential, η_{SEI}, SEI current density, j_{SEI}, and loss of lithium inventory, LLI. There is no visible difference between the two formulations for any of the states.

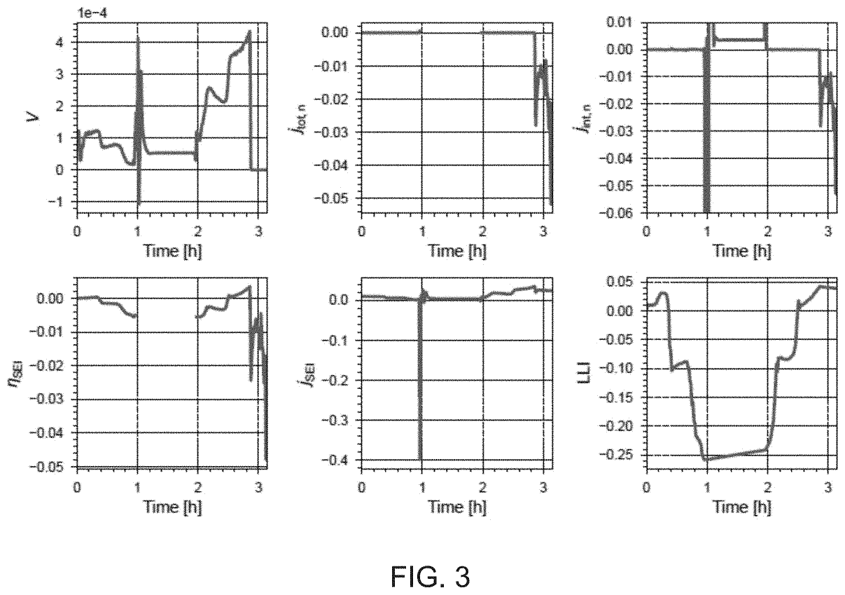

FIG. 3 shows the root mean square percentage error. In each case, the percentage error is well below 1% in all the states. The only exception is j_{int,n} at the transitions between discharge and rest, and rest and charge, which is due to the two solutions reaching the cut-off discharge voltage at slightly different times. This error is quickly corrected and does not cause error in the other states of interest such as voltage and loss of lithium inventory.

The simulation time with the ODE formulation is three times faster than the DAE formulation, with negligible error. Therefore, the ODE formulation was used to report simulation times in the following section.

### 4. Adaptive Inter-Cycle Extrapolation

Some embodiments of the invention provide an algorithm to accelerate battery lifetime simulations using adaptive inter-cycle extrapolation. This can be done in conjunction with the reformulation in discussed above, or separately. Described below is inter-cycle extrapolation. This can be improved on by making the algorithm adaptive, as described below.

Battery cycling is a typical example of a process with multiple timescales. The fast timescale is charge/discharge (‘cycling’), which occurs on the scale of a few hours and is characterized by the State of Charge (SOC). The slow timescale is degradation, which occurs on the scale of months and is characterized by the State of Health (SOH). State of Health can be assumed to be approximately constant over a single cycle, and vary linearly over a few cycles—although there are exceptions at the start and end of life, especially after the ‘knee point’ [Refs. 28, 38].

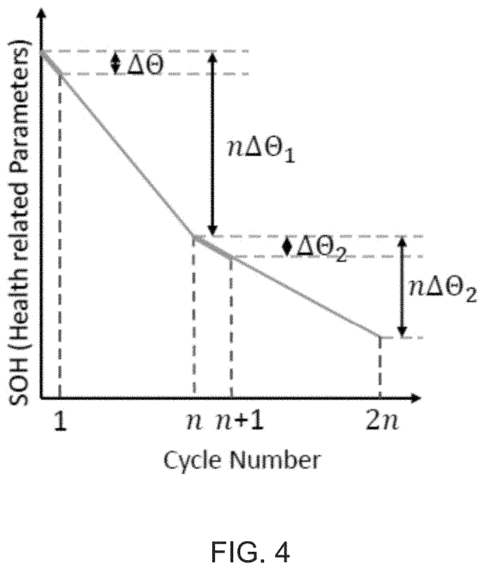

This observation leads to a simple direct extrapolation algorithm for simulating repeated cycles, depicted in FIG. 4: run one cycle, measure the change in each state between the beginning and end of simulation, and extrapolate this over several cycles to initialize the next simulation n cycles later,

x₀^{k}=x_{end}^{k-n}+nΔx^{k-n}, (10)

Δx^{k-n}=x₀^{k-n}−x_{end}^{k-n}. (11)

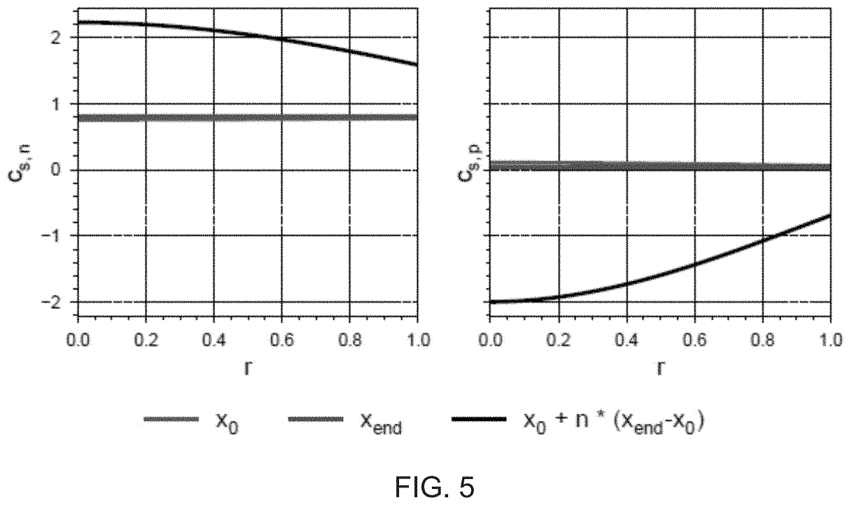

This direct extrapolation algorithm was proposed for fuel cell models by Mayur et al. [Refs. 22, 23] as the ‘time-upscaling method’, and adapted to lithium-ion batteries by Kupper et al. [Ref. 24]. Vora et al. [Ref. 25] proposed a similar algorithm at the same time and called it ‘extrapolation’. However, the direct extrapolation algorithm is suboptimal, as it requires extrapolating values of ‘fine scale’ variables such as particle concentration, which can vary quickly on short timescales. Small changes in the value of ‘fine scale’ variables can lead to large changes after extrapolation, as shown in FIG. 5. Instead, only ‘coarse scale’ variables, which change on longer timescales, should be extrapolated [Ref. 19]. These variables can be explicit states of the model or aggregated from fine scale variables. In the case of the SPM considered here, (1), the coarse scale variables can be used

y=[n_{Li,s},δ_{SEI},ε_{s,n},ε_{s,p}]^{T}. (12)

The three scalar variables δ_{SEI}, ε_{s,n}, and ε_{s,p} are explicit states of the model, but can also be used as coarse scale variables since they change slowly on the degradation timescale (small change over a single cycle). However, the fast-changing particle concentrations c_{s,n} and c_{s,p} can be replaced with the total cyclable lithium, η_{Li,s}, defined as

$${η}_{Li , s} = \frac{3600}{F} ( {θ}_{n} {C}_{n} + {θ}_{p} {C}_{p} ) . \qquad ( 13 )$$

Details about the total cyclable lithium and related ‘degradation modes’ are described below. Given a total cyclable lithium value, the particle concentrations at full charge (and full discharge) can be calculated using (25). These are then used to initialize the next simulation after extrapolation. In summary, the fixed step extrapolation algorithm with step size n is as follows:
1. Simulate one cycle from x₀^{k-n} to obtain x_{end}^{k-n}
2. Calculate y₀^{k-n} and y_{end}^{k-n} using (13)
3. Extrapolate y equivalently to (10) to obtain y₀^{k}
4. Calculate x_{end}^{k} using (25) and repeat

It can be noted that if the model contained algebraic states, such as electric potentials, these would not be included in the y vector as they do not require an initial condition and should be automatically initialized by the solver in a way that satisfies the algebraic equations.

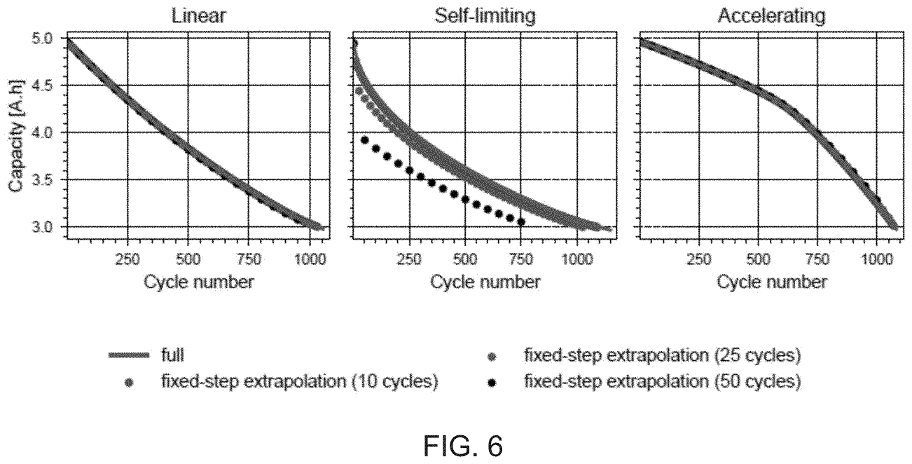

FIG. 6 shows the results of using fixed-step inter-cycle extrapolation, comparing three different step sizes (25, 50, and 100) with the full simulation. In the first and third cases, the underlying degradation in mode-space is linear. Therefore, the fixed-step extrapolation simulations perform well with any step size, since the assumption that degradation rate remains constant holds. However, in the self-limiting case, the fixed-step extrapolation simulations have significant error, with higher error for larger steps. This is because the rate of degradation decreases rapidly at the start of life, so the extrapolating simulations overestimate the rate of degradation.

The results of FIG. 6 show that the inter-cycle extrapolation algorithm should take small steps when the rate of degradation changes quickly, and large steps when the rate of degradation is constant. Therefore, instead of extrapolating by a fixed number of cycles each time, an adaptive algorithm can be used where the size of the extrapolation step depends on how quickly the rate of degradation is changing.

In general, FIG. 6 compares the full simulation to the fixed-step extrapolation algorithm. The fixed-step extrapolation algorithm is accurate in the linear and accelerating cases, where the underlying degradation modes are linear. In the self-limiting case, where degradation is nonlinear, there is significant error from fixed-step extrapolation, with larger error for larger steps.

The degradation system can be written as an ODE:

$$\frac{dy}{dt} = Δ y , \qquad ( 14 )$$

where the y is defined as in (12). “Time” is the number of cycles, and Δy is the change in y from the start to end of the cycle as observed by simulating the cycle. More specifically, each evaluation of Δy, as a function of (t and y), comprises the following:
1. Calculate x₀ from y₀=y using (25)
2. Simulate an entire discharge/charge cycle to obtain x_{end}
3. Calculate y_{end} from x_{end} using (13)
4. Return Δy=y_{end}−y₀

Each evaluation of Δy requires solving an entire discharge/charge cycle and thus is relatively expensive. Equation (14) encodes the degradation that occurs over each cycle into a continuous-time framework that can then be solved by standard numerical integrators. In this context, the fixed-step ‘extrapolation’ method [Refs. 22, 23, 24, 25] is the Forward Euler solution. This can be improved on by using an adaptive numerical method [Refs. 39, 40]. Equation (14) is non-stiff, but evaluating the right-hand side is expensive, so a method with as few right-hand side evaluations as possible is required. A 3(2) Runge-Kutta algorithm [Ref. 41] can be used as implemented in SciPy [Ref. 42]. Since the evolution of the slow timescale ODE is monotonic and almost linear, low tolerances (10⁻² for both relative and absolute tolerance) can be used, enabling the ODE solver to take large steps at the required accuracy.

The cycle-adaptive algorithm is implemented in the open-source battery modeling package PyBaMM [Ref. 27] and as such can be used with any model in the library. The ‘slow’ degradation ODE is solved using 3(2) Runge-Kutta in SciPy [Ref. 42]. Each ‘fast’ cycle simulation is solved using the method of lines, first discretizing the PDEs spatially using finite volumes with 30 grid points in each particle and then solving the resulting ODE system using CVODE from SUNDIALS via CasADi [Ref. 33, 34]. The 60% capacity termination condition is implemented as a stopping condition in the ‘slow’ degradation ODE solver.

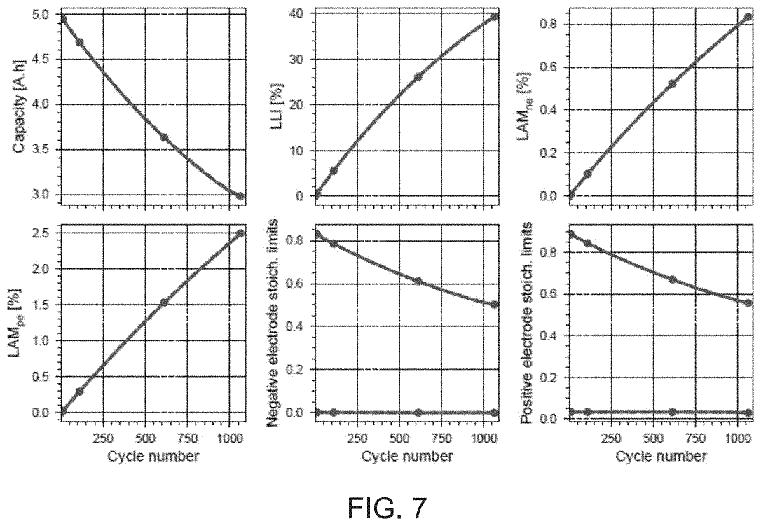

Results for the three cases (linear, self-limiting, and accelerating) are shown in FIGS. 7 to 9 respectively. Shown are the thermodynamic capacity and stoichiometry limits, calculated using (25), as well as the three degradation modes loss of lithium inventory (LLI) and loss of active material in the negative (LAM_{NE}) and positive (LAM_{PE}) electrodes. In each case, the solid red lines show the full simulation and the dashed blue lines show the adaptive inter-cycle extrapolation simulation, with blue dots showing which cycles were chosen by the adaptive ODE solver to solve the degradation ODE (14). The adaptive inter-cycle extrapolation algorithm accurately captures the evolution of each variable in every case. The results are discussed in further detail below.

In the linear case (FIG. 7), the degradation rate is approximately constant and each underlying degradation mode is approximately linear versus cycle number. This leads to approximately linear changes in the capacity and stoichiometry limits, and the adaptive simulation is accurate while able to take a small number of large steps while maintaining accuracy.

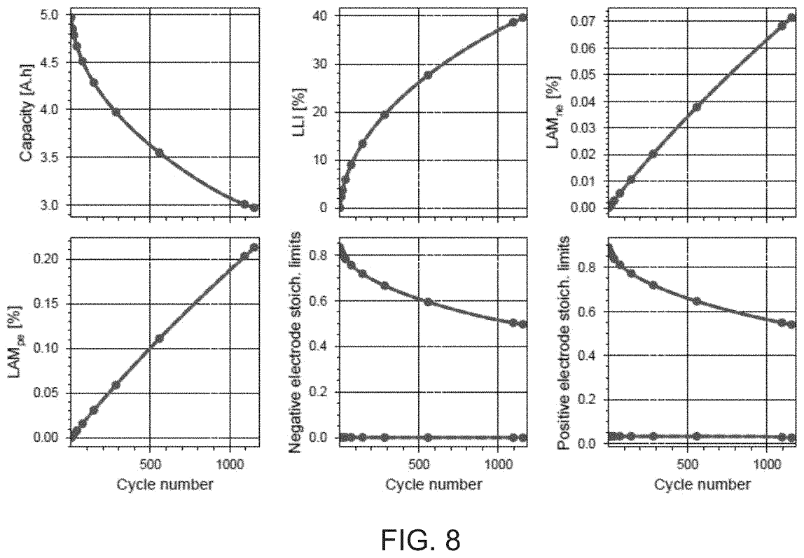

In the self-limiting case (FIG. 8), the rate of degradation slows down as the cell degrades, driven by self-limiting SEI growth (and hence self-limiting LLI). This effect is most pronounced in the first few hundred cycles. Therefore, the adaptive simulation needs to take small steps at the start of life to resolve the changing rate of degradation, and is able to take larger steps towards end-of-life when degradation becomes more linear. This example demonstrates the power of the adaptive simulation to capture changing degradation rates.

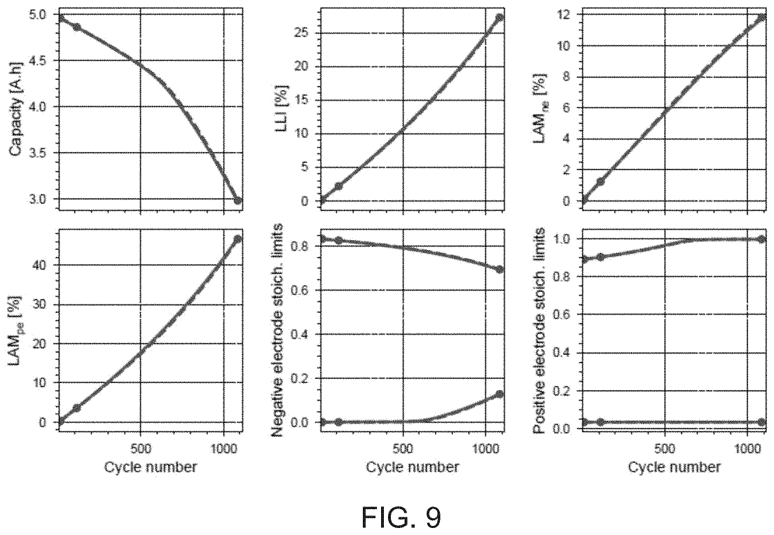

Finally, in the accelerating degradation case (FIG. 9), there is a knee point in the capacity fade curve around cycle 600 where capacity fade becomes much faster. Despite this, the adaptive simulation is able to take very large steps. This is because the degradation in mode-space, which is where the extrapolation happens, is approximately linear. Here, the cause of the knee point is that the maximum positive electrode stoichiometry reaches 1 around 600 cycles and cannot go above it, causing a nonlinearity in the minimum electrode stoichiometry limit and the capacity (all of which are related through (25)). This effect has previously been reported in the literature [Ref. 43].

In summary, for this model, the capacity fade is affected by, firstly, the relative rate of loss of lithium inventory and loss of active material, and secondly, whether the SEI growth is reaction-limited or diffusion-limited. If loss of lithium inventory due to side reactions is faster than loss of active material in both electrodes, so that the utilization of each electrode decreases as the cell ages, degradation is linear or self-limiting. If loss of active material is faster in either electrode, leading to a wider utilization, eventually one of the electrodes will saturate, causing a knee point (‘accelerating’ capacity fade). Within linear and self-limiting degradation, the capacity fade is approximately linear if the SEI growth is reaction-limited, and the rate slows if the SEI growth is diffusion-limited.

In Table 4, the simulation time for the full simulation and adaptive simulation are compared. The adaptive simulations solve two orders of magnitude fewer cycles, and hence achieve an almost two order of magnitude speed-up. Adaptive simulations can therefore provide almost immediate feedback on a human timescale. The time taken to stay small even when simulating tens of thousands of cycles, since larger steps will be possible in that case. Note that the number of cycles solved by the adaptive simulation is not equal to the number of blue dots in FIGS. 7 to 9 (roughly three times larger). This is because each blue dot in FIGS. 7 to 9 requires three cycle evaluations for the third-order adaptive ODE solver used here.

TABLE 4

| | Full simulation | | | Adaptive simulation | |
|---|---|---|---|---|---|
| | Cycles to 60% | Cycles solved | Time take (s) | Cycles solved | Time taken (s) |
| Linear | 1055 | 1055 | 173 | 13 | 4.5 |
| Self-limiting | 1200 | 1200 | 178 | 31 | 11.2 |
| Accelerating | 1085 | 1085 | 171 | 10 | 3.9 |

Table 4 shows the number of cycles solved and time taken for the full and adaptive simulations in each case. The adaptive simulations solve around 20-40 times fewer cycles than the full simulations, since they perform inter-cycle extrapolation, and simulate the entire life of the battery in around 5-10 seconds. Simulations performed on an Apple M1 CPU.

Embodiments of the invention provide foundations for an adaptive inter-cycle extrapolation algorithm that can simulate the entire lifetime of lithium-ion batteries in a few seconds, and shown the approach to work well in a Single Particle Model with SEI formation and loss of active material. Examples herein will enable researchers to study battery degradation with very rapid feedback on lifetime performance, so that different degradation mechanisms and the coupling between them can better be understood. The cycle-adaptive simulations can also be used to speed up parameter estimation algorithms for determining the parameters of a degradation model, such as those in Table 3.

The model for SEI kinetics from Yang et al. [Ref. 28] is

$${j}_{SEI} = - {Fk}_{SEI} {c}_{EC}^{s} exp ( - \frac{{α}_{SEI} F {η}_{SEI}}{RT} ) , \qquad ( 15 a )$$

$$- {D}_{SEI} \frac{{c}_{EC}^{s} - {c}_{EC}^{bulk}}{{δ}_{SEI}} = - \frac{{α}_{SEI} {j}_{SEI}}{F} . \qquad ( 15 b )$$

This is a linear system for j_{SEI} and c^{s}_{EC}, and so we can eliminate the surface concentration of EC, c^{s}_{EC}, to avoid having to solve an additional algebraic equation:

$$\begin{matrix}{j}_{SEI} = \frac{- {c}_{EC}^{bulk}}{1 / {Fk}_{SEI} exp ( - {α}_{SEI} F {η}_{SEI} / RT ) + {α}_{SEI} {δ}_{SEI} / {D}_{SEI} F} \\ = {f}_{SEI} ( {η}_{SEI} , {δ}_{SEI} ) .\end{matrix} \qquad ( 16 )$$

The relative size of the two terms in (16) governs the SEI kinetics. If the first term is larger, the SEI growth is reaction-limited. If the second term is larger, the SEI growth is diffusion-limited.

In general, battery degradation can occur through a number of mechanisms, including but not limited to SEI layer growth, lithium plating, mechanical effects in the particles, and electrolyte oxidation [Refs. 44, 45, 29]. To classify these mechanisms, it is helpful to use degradation modes [Refs. 44, 45]. The three main degradation modes are loss of lithium inventory (LLI), loss of active material (LAM) in the negative electrode, and LAM in the positive electrode.

Loss of active material is generally caused by mechanical effects. This leads to a reduction in the capacity of the electrodes, Cₖ:

$${LAM}_{k} = ( 1 - \frac{{C}_{k}}{{C}_{k}^{init}} ) \times 100 = - \frac{1}{{C}_{k}^{init}} {\int }_{0}^{t} \frac{{dC}_{k}}{dt} dt \times 100. \qquad ( 17 )$$

The charge capacity (in Ah) of the electrodes can be defined as

$${C}_{k} = \frac{{ε}_{s , k} {AL}_{k} {c}_{s , k}^{max} F}{3600} , \qquad ( 18 )$$

and so any changes in capacity are caused by changes in active material volume fraction, ε_{s,k}. Degradation models that include LAM usually do so via a differential equation for either the active material volume fraction or electrode capacity. Loss of lithium inventory is defined as

$$LLI = ( 1 - \frac{{n}_{Li , s}}{{n}_{Li , s}^{init}} ) \times 100 = - \frac{1}{{n}_{Li , s}^{init}} {\int }_{0}^{t} \frac{{dn}_{Li , s}}{dt} dt \times 100 , \qquad ( 19 )$$

where η_{Li,s} is the total number of moles of cyclable lithium in the particles,

$${η}_{Li , s} = \frac{3600}{F} ( {θ}_{n} {C}_{n} + {θ}_{p} {C}_{p} ) , \qquad ( 20 )$$

where θₙ and θₚ are the scaled volumed-averaged negative and positive particle concentrations (or ‘electrode stoichiometries’) defined in (29). At any time, the total current density in each electrode, jₜₒₜ, must be equal to the sum of the intercalation density, jᵢₙₜ, and the total current density of side reactions, j_{side},

j_{tot,k}=j_{int,k}+j_{side,k}, k∈{n,p}. (21)

We define J_{r,k} to be the total current for reaction r in domain Ωₖ,

J_{r,k}=∫^{Ω}ₖa_{s,k}j_{r,k}dV, (22)

This gives the relationship derived below,

$$\frac{{dn}_{Li , s}}{dt} = \frac{{I}_{side}}{F} + \frac{3600}{F} ( {θ}_{n} \frac{{dC}_{n}}{dt} + {θ}_{p} \frac{{dC}_{p}}{dt} ) , \qquad ( 23 )$$

and so, by (19), LLI can be decomposed into three parts,

$$LLI = {\underbrace{\frac{1}{{n}_{\text{?} , s}^{init}} {\int }_{0}^{t} \frac{{I}_{side}}{F} dt}}_{{LLI}_{\text{?}}} - \frac{3600 {C}_{n}^{\text{?}}}{{Fn}_{\text{?} , s}^{init}} {\underbrace{\frac{1}{{C}_{n}^{\text{?}}} {\int }_{0}^{t} {θ}_{n} \frac{{dC}_{n}}{dt} dt}}_{{LAM}_{\text{?}}} - \frac{3600 {C}_{p}^{\text{?}}}{{Fn}_{\text{?} , s}^{init}} {\underbrace{\frac{1}{{C}_{p}^{\text{?}}} {\int }_{0}^{t} {θ}_{p} \frac{{dC}_{p}}{dt} dt}}_{{LAM}_{\text{?}}} , \qquad ( 24 )$$

$$\text{?} \text{indicates text missing or illegible when filed}$$

where LLI_{r×n} is the LLI due to side reactions and LAM_{liNE} and LAM_{liPE} are loss of lithiated active material, with loss of delithiated active material defined as LAM_{de}=LAM−LAMₗᵢ. Equation (23) shows that loss of lithium inventory occurs not only as a result of side reactions (I_{side}/F) but also as a result of loss of active material (dCₖ/dt).

Some degradation mechanisms, such as pore clogging, do not contribute to either LLI or LAM, but instead to an increase in the internal resistance of the cell. This is sometimes characterized as Ohmic Resistance Increase (ORI), though this term can be misleading as resistance increases can depend nonlinearly on current (for example, if associated with larger concentration gradients due to decrease tortuosity).

It is useful to relate the degradation modes to the stoichiometric limits θₙ⁰, θₙ¹⁰⁰, θₚ⁰, and θₚ¹⁰⁰, where the subscript indicates SOC. For any given j_{Lis}, Cₙ, Cₚ, and voltage limits Vₘᵢₙ and Vₘₐₓ, the stoichiometric limits can be found using the following equations [Ref. 46]:

$${n}_{\text{?}} = \frac{3600}{F} ( {θ}_{n}^{100} {C}_{n} + {θ}_{p}^{100} {C}_{p} ) , \qquad ( 25 a )$$

$${C}_{n} ( {θ}_{n}^{100} - {θ}_{n}^{0} ) = {C}_{p} ( {θ}_{p}^{0} - {θ}_{p}^{100} ) , \qquad ( 25 b )$$

$${V}_{min} = {U}_{p} ( {θ}_{p}^{0} ) - {U}_{n} ( {θ}_{n}^{0} ) , \qquad ( 25 c )$$

$${V}_{max} = {U}_{p} ( {θ}_{p}^{100} ) - {U}_{n} ( {θ}_{n}^{100} ) . \qquad ( 25 d )$$

$$\text{?} \text{indicates text missing or illegible when filed}$$

The capacity of the cell is then given by

C=Cₙ(θₙ¹⁰⁰−θₙ⁰)=Cₚ(θₚ⁰−θₚ¹⁰⁰). (26)

### and its State of Charge by

$$z = \frac{Q}{C} = {C}_{p} \frac{{θ}_{p} - {θ}_{p}^{100}}{C} = {C}_{n} \frac{{θ}_{n}^{100} - {θ}_{n}}{C} . \qquad ( 27 )$$

Equation (26) gives the capacity of the cell without needing to simulate a full low C-rate discharge, and equation (25) can be used to initialize a simulation given SOC while respecting the balance of lithium and conserving total lithium.

A microscale particle domain Ωₛ with surface ∂Ωₛ, volume Vₛ, and surface area Aₛ, can be considered inside a macroscale electrode domain Ωₜₒₜ with volume Vₜₒₜ=AL. Mass conservation in the particle gives

$$\frac{\partial {c}_{s}}{\partial t} = - ∇ {( \cdot N )}_{s} , \qquad ( 28 a )$$

$$r ∈ {Ω}_{s} ,$$

$${N}_{s} \cdot n = \frac{{j}_{\text{?}}}{F} , \qquad ( 28 b )$$

$$on \partial {Ω}_{s} ,$$

$$\text{?} \text{indicates text missing or illegible when filed}$$

where cₛ is the molar concentration of intercalated lithium, Nₛ is the flux of lithium in the particles, Rₛ is particle radius, and j is the intercalation current.

Electrode stoichiometry can be defined to be the particle concentration averaged over both particle domain Ωₛ and electrode domain Ωₜₒₜ, and normalized with electrode volume and particle volume:

$$θ = \frac{1}{AL} {\int }_{{Ω}_{\text{?}}} [ \frac{1}{{V}_{s} {c}_{s}^{max}} {\int }_{{Ω}_{\text{?}}} {c}_{s} dr ] dx . \qquad ( 29 )$$

$$\text{?} \text{indicates text missing or illegible when filed}$$

Differentiating in time and substituting (28a) gives

$$\frac{d θ}{dt} = \frac{1}{AL} {\int }_{{Ω}_{\text{?}}} {\int }_{{Ω}_{\text{?}}} [ \frac{1}{{V}_{s} {c}_{s}^{max}} {\int }_{{Ω}_{\text{?}}} - ∇ {( \cdot N )}_{s} dr ] dx , \qquad ( 30 )$$

$$\text{?} \text{indicates text missing or illegible when filed}$$

and applying the Divergence Theorem and substituting (28b) gives

$$\frac{d θ}{dt} = \frac{1}{AL} {\int }_{{Ω}_{\text{?}}} [ - \frac{{A}_{s} {j}_{int}}{{V}_{s} {c}_{s}^{max} F} ] dx , \qquad ( 31 )$$

$$\text{?} \text{indicates text missing or illegible when filed}$$

since Aₛ=∫_{∂Ω}_{ₛ}1dS and j is uniform over the surface of a particle. Now, if there are Nₜₒₜ particles in the electrode, then by definition

εₛVₜₒₜ=NₜₒₜVₛ, aₛVₜₒₜ=NₜₒₜAₛ, (32)

and so the surface area to volume ratio is related to the porosity through

$${a}_{s} = \frac{{\text{?}}_{s} {A}_{s}}{{V}_{s}} . \qquad ( 33 )$$

$$\text{?} \text{indicates text missing or illegible when filed}$$

For spherical particles, this gives the well-known relation aₛ=3ϵₛ/Rₛ. Substituting (33) into (31) gives

$$\frac{d θ}{dt} = - \frac{1}{{\text{?}}_{s} {ALc}_{s}^{max} F} {\int }_{{Ω}_{\text{?}}} {a}_{s} {j}_{int} dx , \qquad ( 34 )$$

$$\text{?} \text{indicates text missing or illegible when filed}$$

and (22) and (18) can be substituted to obtain

$$\frac{{d θ}_{k}}{dt} = \frac{{J}_{int , k}}{3600 {C}_{k}} . \qquad ( 35 )$$

For simplicity, εₛ can be assumed to be independent of x, but the derivation can be adapted to the case where εₛ is a function of x.

The rate of change of total lithium can be found. Differentiating (20) in time and applying the chain rules gives

$$\frac{{dn}_{Li , s}}{dt} = \frac{3600}{F} ( {C}_{n} \frac{{d θ}_{n}}{dt} + {C}_{p} \frac{{d θ}_{p}}{dt} + {θ}_{n} \frac{{dC}_{n}}{dt} + {θ}_{p} \frac{{dC}_{p}}{dt} ) . \qquad ( 36 )$$

### Substituting (35),

$$\frac{{dn}_{Li , s}}{dt} = - \frac{1}{F} ( {J}_{int , n} + {J}_{int , p} ) + \frac{3600}{F} ( {θ}_{n} \frac{{dC}_{n}}{dt} + {θ}_{p} \frac{{dC}_{p}}{dt} ) . \qquad ( 37 )$$

Now, integrating (21) over the entire electrode gives

J_{int,n}+J_{side,n}=I, (38a)

J_{int,p}+J_{side,p}=−I, (38b)

and so, defining the total side reaction current I_{side}=J_{side,n}+J_{side,p},

$$- \frac{1}{F} ( {J}_{int , n} + {J}_{int , p} ) = \frac{1}{F} ( {J}_{side , n} + {J}_{side , p} ) = \frac{{I}_{side}}{F} . \qquad ( 39 )$$

Hence

$$\frac{{dn}_{Li , s}}{dt} = \frac{{I}_{side}}{F} + \frac{3600}{F} ( {θ}_{n} \frac{{dC}_{n}}{dt} + {θ}_{p} \frac{{dC}_{p}}{dt} ) . \qquad ( 40 )$$

### List of Symbols and Acronyms

### Acronyms

EC=ethylene-carbonate
LAM=loss of active material
LLI=loss of lithium inventory
SEI=Solid electrolyte interphase

### Variables

C=capacity; units=Ah
I=current; units=A
J=current; units=A
N=molar flux; units=mol m⁻² s⁻¹
V=voltage; units=V
a=surface area to volume ration; units=m⁻¹
c=concentration; units=mol m⁻³
i=current density; units=A m⁻²
j=interfacial current density; units=A m⁻²
nuL=lithium inventory; units=mol
r=radial coordinate
t=time
δ=thickness; units=m
εₛ=active material volume fraction
η=overpotential; units=V
Φ=potential; units=V
θ=stoichiometry
σ=stress; units=Pa

### Parameters

See also Tables 2 and 3.
F=Faraday's constant; units=mol m⁻³
L=electrode thickness; units=m
R=ideal gas constant; units=J mol⁻¹ K⁻¹
R_{film}=SEI film resistivity; units=Ωm
Rₖ=particle radius; units=m
U=open-circuit potential; units=V
i₀=intercalation exchange-current density; units=A m⁻²

### Subscripts

e=electrolyte phase
int=intercalation
k=electrode k (n or p)
n=negative electrode
p=positive electrode
s=solid phase
tot=total

### Superscripts

surf=at the surface (of particle)
0=leading-order in asymptotic expansion
1=first-order in asymptotic expansion

### REFERENCES

[1] V. Sulzer, P. Mohtat, A. Aitio, S. Lee, Y. T. Yeh, M. U. Khan, J. W. Lee, J. B. Siegel, A. David, and A. G. Stefanopoulou, “The challenge of battery lifetime prediction from field data,” Joule, pp. 1-20, 2021. [Online]. Available: https://doi.org/10.1016/j.joule.2021.06.005
[2] H. C. Hesse, M. Schimpe, D. Kucevic, and A. Jossen, “Lithium-ion battery storage for the grid—A review of stationary battery storage system design tailored for applications in modern power grids,” Energies, vol. 10, no. 12, 2017.
[3] A. Bocca and D. Baek, “Optimal life-cycle costs of batteries for different electric cars,” 2020 AEIT International Conference of Electrical and Electronic Technologies for Automotive, AEIT AUTOMOTIVE 2020, no. i, pp. 1-6, 2020.
[4] D. A. Howey, S. A. Roberts, V. Viswanathan, A. Mistry, M. Beuse, E. Khoo, S. C. Decaluwe, and V. Sulzer, “Free Radicals: Making a Case for Battery Modeling,” The Electrochemical Society Interface, vol. 29, no. 30, 2020.
[5] K. A. Smith, C. D. Rahn, and C. Y. Wang, “Control oriented 1D electrochemical model of lithium ion battery,” Energy Conversion and Management, vol. 48, no. 9, pp. 2565-2578, 2007.
[6] L. Cai and R. E. White, “Reduction of Model Order Based on Proper Orthogonal Decomposition for Lithium-Ion Battery Simulations,” Journal of The Electrochemical Society, vol. 156, no. 3, p. A154, 2009.
[7] P. W. C. Northrop, B. Suthar, V. Ramadesigan, S. Santhanagopalan, R. D. Braatz, and V. R. Subramanian, “Efficient Simulation and Reformulation of Lithium-Ion Battery Models for Enabling Electric Transportation,” Journal of The Electrochemical Society, vol. 161, no. 8, pp. E3149-E3157, 2014.
[8] V. R. Subramanian, V. Boovaragavan, and V. D. Diwakar, “Toward real-time simulation of physics based lithium-ion battery models,” Electrochemical and Solid-State Letters, vol. 10, no. 11, pp. 255-260, 2007.
[9] P. Barai, K. Smith, C.-F. Chen, G.-H. Kim, and P. P. Mukherjee, “Reduced Order Modeling of Mechanical Degradation Induced Performance Decay in Lithium-Ion Battery Porous Electrodes,” Journal of The Electrochemical Society, vol. 162, no. 9, pp. A1751-A1771, 2015.
[10] D. Di Domenico, A. G. Stefanopoulou, and G. Fiengo, “Lithium-Ion Battery State of Charge and Critical Surface Charge Estimation Using an Electrochemical Model-Based Extended Kalman Filter,” Journal of Dynamic Systems, Measurement, and Control, vol. 132, no. 6, p. 061302, 2010. [Online]. Available: http://www.asme.org/about-asme/terms-of-usehttp://dynamicsystems.asmedigitalcollection.asme.org/article.aspx?articleid=1414570
[11] S. J. Moura, F. B. Argomedo, R. Klein, A. Mirtabatabaei, and M. Krstic, “Battery State Estimation for a Single Particle Model With Electrolyte Dynamics,” IEEE Transactions on Control Systems Technology, vol. 25, no. 2, pp. 453-468, 2017. [Online]. Available: https://ecal.berkeley.edu/pubs/SPMe-Obs-Journal-Final.pdf
[12] S. G. Marquis, V. Sulzer, R. Timms, C. P. Please, and S. Jon Chapman, “An asymptotic derivation of a single particle model with electrolyte,” Journal of the Electrochemical Society, vol. 166, no. 15, pp. A3693-A3706, 2019.
[13] F. Brosa Planella, M. Sheikh, and W. D. Widanage, “Systematic derivation and validation of a reduced thermal-electrochemical model for lithium-ion batteries using asymptotic methods,” Electrochimica Acta, vol. 388, p. 138524, 2021. [Online]. Available: https://doi.org/10.1016/j.electacta.2021.138524
[14] I. R. Moyles, M. G. Hennessy, T. G. Myers, and B. R. Wetton, “Asymptotic reduction of a porous electrode model for lithium-ion batteries,” SIAM Journal on Applied Mathematics, vol. 79, no. 4, pp. 1528-1549, 5 2019. [Online]. Available: https://epubs.siam.org/doi/10.1137/18M1189579
[15] G. Richardson, I. Korotkin, R. Ranom, M. Castle, and J. Foster, “Generalised single particle models for high-rate operation of graded lithium-ion electrodes: Systematic derivation and validation,” Electrochimica Acta, vol. 339, p. 135862, 4 2020. [Online]. Available: https://linkinghub.elsevier.com/retrieve/pii/S0013468620302541
[16] T. L. Kirk, J. Evans, C. P. Please, and S. J. Chapman, “Modelling Electrode Heterogeneity in Lithium-Ion Batteries: Unimodal and Bimodal Particle-Size Distributions,” arXiv, 2020.
[17] S. G. Marquis, R. Timms, V. Sulzer, C. P. Please, and S. J. Chapman, “A Suite of Reduced-Order Models of a Single-Layer Lithium-Ion Pouch Cell,” Journal of The Electrochemical Society, vol. 167, no. 14, p. 140513, 2020.
[18] R. Timms, S. G. Marquis, V. Sulzer, C. P. Please, and S. J. Chapman, “Asymptotic reduction of a lithium-ion pouch cell model,” SIAM Journal on Applied Mathematics, vol. 81, no. 3, pp. 765-788, 2021.
[19] I. G. Kevrekidis and G. Samaey, “Equation-free multiscale computation: Algorithms and applications,” Annual Review of Physical Chemistry, vol. 60, pp. 321-344, 2009.
[20] G. Wang, “Equation-Free System-Level Modeling and Analytics in Energy Processing Systems,” Ph.D. dissertation, Tufts University, 2019.
[21] J. K. Kevorkian and J. D. Cole, Multiple scale and singular perturbation methods. Springer Science & Business Media, 2012.
[22] M. Mayur, S. Strahl, A. Husar, and W. G. Bessler, “A multi-timescale modeling methodology for PEMFC performance and durability in a virtual fuel cell car,” International Journal of Hydrogen Energy, vol. 40, no. 46, pp. 16 466-16 476, 2015.
[23] M. Mayur, B. Weißhar, and W. G. Bessler, “Simulation-based degradation assessment of lithium-ion batteries in a hybrid electric vehicle,” in 68th Annual Meeting of the International Society of Electrochemistry, Providence, USA (September 2017): Book of Abstracts, ser. 68th Annual Meeting of the International Society of Electrochemistry, Providence, USA (September 2017): Book of Abstracts, 2017, p. 854.
[24] C. Kupper, B. Weißhar, S. Rißmann, and W. G. Bessler, “End-of-Life Prediction of a Lithium-Ion Battery Cell Based on Mechanistic Aging Models of the Graphite Electrode,” Journal of The Electrochemical Society, vol. 165, no. 14, pp. A3468-A3480, 2018.
[25] A. P. Vora, X. Jin, V. Hoshing, G. Shaver, S. Varigonda, and W. E. Tyner, “Integrating battery degradation in a cost of ownership framework for hybrid electric vehicle design optimization,” Proceedings of the Institution of Mechanical Engineers, Part D: Journal of Automobile Engineering, vol. 233, no. 6, pp. 1507-1523, 2019.
[26] L. Trefethen, “Ten digit algorithms,” Mitchell Lecture, June, no. June, 2005. [Online]. Available: https://people.maths.ox.ac.uk/trefethen/publication/PDF/2005 114.pdf
[27] V. Sulzer, S. Marquis, R. Timms, M. Robinson, and S. J. Chapman, “Python Battery Mathematical Modelling (PyBaMM),” Journal of Open Research Software, vol. 9, no. 1, p. 14, 2021.
[28] X. G. Yang, Y. Leng, G. Zhang, S. Ge, and C. Y. Wang, “Modeling of lithium plating induced aging of lithium-ion batteries: Transition from linear to nonlinear aging,” Journal of Power Sources, vol. 360, pp. 28-40, 2017. [Online]. Available: http://dx.doi.org/10.1016/j.jpowsour.2017.05.110
[29] J. M. Reniers, G. Mulder, and D. A. Howey, “Review and Performance Comparison of Mechanical-Chemical Degradation Models for Lithium-Ion Batteries,” Journal of The Electrochemical Society, vol. 166, no. 14, pp. A3189-A3200, 2019.
[30] I. Laresgoiti, S. K\ddot{ } abitz, M. Ecker, and D. U. Sauer, “Modeling mechanical degradation in lithium ion batteries during cycling: Solid electrolyte interphase fracture,” Journal of Power Sources, vol. 300, pp. 112-122, 2015.
[31] W. Ai, L. Kraft, J. Sturm, A. Jossen, and B. Wu, “Electrochemical Thermal-Mechanical Modelling of Stress Inhomogeneity in Lithium-Ion Pouch Cells,” Journal of The Electrochemical Society, vol. 167, no. 1, p. 013512, 2020.
[32] P. Mohtat, S. Lee, V. Sulzer, J. B. Siegel, and A. G. Stefanopoulou, “Differential Expansion and Voltage Model for Li-ion Batteries at Practical Charging Rates,” Journal of The Electrochemical Society, vol. 167, no. 11, p. 110561, 2020.
[33] J. A. E. Andersson, J. Gillis, G. Horn, J. B. Rawlings, and M. Diehl, “CasADi—A software frame-work for nonlinear optimization and optimal control,” Mathematical Programming Computation, vol. 11, pp. 1-36, 2019.
[34] A. C. Hindmarsh, P. N. Brown, K. E. Grant, S. L. Lee, R. Serban, D. E. Shumaker, and C. S. Woodward, “SUNDIALS: Suite of nonlinear and differential/algebraic equation solvers,” ACM Transactions on Mathematical Software (TOMS), vol. 31, no. 3, pp. 363-396, 2005.
[35] M. Safari, M. Morcrette, A. Teyssot, and C. Delacourt, “Multimodal Physics-Based Aging Model for Life Prediction of Li-Ion Batteries,” Journal of The Electrochemical Society, vol. 156, no. 3, p. A145, 12 2009. [Online]. Available: https://iopscience.iop.org/article/10.1149/1.3043429/meta
[36] V. Sulzer, S. J. Chapman, C. P. Please, D. A. Howey, and C. W. Monroe, “Faster Lead-Acid Battery Simulations from Porous-Electrode Theory: Part I. Physical Model,” Journal of The Electrochemical Society, vol. 166, no. 12, pp. A2363-A2371, 2019.
[37] V. Sulzer, “Mathematical Modelling of Lead-Acid Batteries,” Ph.D. dissertation, University of Oxford, 2019.
[38] S. Atalay, M. Sheikh, A. Mariani, Y. Merla, E. Bower, and W. D. Widanage, “Theory of battery ageing in a lithium-ion battery: Capacity fade, nonlinear ageing and lifetime prediction,” Journal of Power Sources, vol. 478, p. 229026, 2020. [Online]. Available: https://doi.org/10.1016/j.jpowsour.2020.229026
[39] R. Rico-Martinez, C. W. Gear, and I. G. Kevrekidis, “Coarse projective kMC integration: For-ward/reverse initial and boundary value problems,” Journal of Computational Physics, vol. 196, no. 2, pp. 474-489, 2004.
[40] S. L. Lee and C. W. Gear, “Second-order accurate projective integrators for multiscale problems,” Journal of Computational and Applied Mathematics, vol. 201, no. 1, pp. 258-274, 2007.
[41] P. Bogacki and L. F. Shampine, “A 3(2) pair of Runge-Kutta formulas,” Applied Mathematics Letters, vol. 2, no. 4, pp. 321-325, 1989.
[42] P. Virtanen, R. Gommers, T. E. Oliphant, M. Haberland, T. Reddy, D. Cournapeau, E. Burovski, P. Peterson, W. Weckesser, J. Bright, S. J. van der Walt, M. Brett, J. Wilson, K. J. Millman, N. Mayorov, A. R. Nelson, E. Jones, R. Kern, E. Larson, C. J. Carey, Polat, Y. Feng, E. W. Moore, J. VanderPlas, D. Laxalde, J. Perktold, R. Cimrman, I. Henriksen, E. A. Quintero, C. R. Harris, A. M. Archibald, A. H. Ribeiro, F. Pedregosa, P. van Mulbregt, A. Vijaykumar, A. P. Bardelli, A. Rothberg, A. Hilboll, A. Kloeckner, A. Scopatz, A. Lee, A. Rokem, C. N. Woods, C. Fulton, C. Masson, C. H\ddot{ } aggstr\ddot{ } om, C. Fitzgerald, D. A. Nicholson, D. R. Hagen, D. V. Pasech-nik, E. Olivetti, E. Martin, E. Wieser, F. Silva, F. Lenders, F. Wilhelm, G. Young, G. A. Price G. L. Ingold, G. E. Allen, G. R. Lee, H. Audren, I. Probst, J. P. Dietrich, J. Silterra, J. T. Web-ber, J. Slavi\check{ } c, J. Nothman, J. Buchner, J. Kulick, J. L. Sch\ddot{ } onberger, J. V. de Miranda Cardoso, J. Reimer, J. Harrington, J. L. C. Rodr\acute{ } iguez, J. Nunez-Iglesias, J. Kuczynski, K. Tritz, M. Thoma, Newville, M. Ku\ddot{ } mmerer, M. Bolingbroke, M. Tartre, M. Pak, N. J. Smith, N. Nowaczyk, Shebanov, O. Pavlyk, P. A. Brodtkorb, P. Lee, R. T. McGibbon, R. Feldbauer, S. Lewis, S. Tygier, S. Sievert, S. Vigna, S. Peterson, S. More, T. Pudlik, T. Oshima, T. J. Pingel, T. P. Robitaille, T. Spura, T. R. Jones, T. Cera, T. Leslie, T. Zito, T. Krauss, U. Upadhyay, Y. O. Halchenko, and Y. V\acute{ } azquez-Baeza, “SciPy 1.0: fundamental algorithms for scientific computing in Python,” Nature Methods, vol. 17, no. 3, pp. 261-272, 2020.
[43] X. Lin, J. Park, L. Liu, Y. Lee, A. M. Sastry, and W. Lu, “A Comprehensive Capacity Fade Model and Analysis for Li-Ion Batteries,” Journal of The Electrochemical Society, vol. 160, no. 10, pp. A1701-A1710, 8 2013. [Online]. Available: https://iopscience.iop.org/article/10.1149/2.040310jeshttps://iopscience.iop.org/article/10.1149/2.040310jes/meta
[44] C. R. Birkl, M. R. Roberts, E. McTurk, P. G. Bruce, and D. A. Howey, “Degradation diagnostics for lithium ion cells,” Journal of Power Sources, vol. 341, pp. 373-386, 2 2017. [Online]. Available: https://linkinghub.elsevier.com/retrieve/pii/S0378775316316998
[45] J. S. Edge, S. O'Kane, R. Prosser, N. D. Kirkaldy, A. N. Patel, A. Hales, A. Ghosh, W. Ai, J. Chen, J. Yang, S. Li, M. C. Pang, L. Bravo Diaz, A. Tomaszewska, M. W. Marzook, K. N. Radhakrishnan, H. Wang, Y. Patel, B. Wu, and G. J. Offer, “Lithium ion battery degradation: what you need to know,” Physical Chemistry Chemical Physics, vol. 23, no. 14, pp. 8200-8221, 2021.
[46] P. Mohtat, S. Lee, J. B. Siegel, and A. G. Stefanopoulou, “Towards better estimability of electrode-specific state of health: Decoding the cell expansion,” Journal of Power Sources, vol. 427, no. February, pp. 101-111, 2019. [Online]. Available: https://doi.org/10.1016/j.jpowsour.2019.03.104
[47] Mistry et al., “A Minimal Information Set To Enable Verifiable Theoretical Battery Research”, ACS Energy Lett. 2021, 6, 3831-3835.
   The citation of any document is not to be construed as an admission that it is prior art with respect to the present invention.

Although the invention has been described in considerable detail with reference to certain embodiments, one skilled in the art will appreciate that the present invention can be practiced by other than the described embodiments, which have been presented for purposes of illustration and not of limitation. Therefore, the scope of the appended claims should not be limited to the description of the embodiments contained herein.

What is claimed is:

1. A method for manufacturing an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles, the method comprising:
(a) selecting at least one cell component selected from the group consisting of electrolytes, cathode active materials, and anode active materials, the at least one cell component causing the degradation of the cell;
(b) determining a nominal discharge capacity for the cell at a state of health of 100%;
(c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the cell cycles are initialized based on a rate of degradation over a plurality of previous cycles and wherein a time at which to simulate the next cycle is chosen based on the rate of degradation over the plurality of previous cycles; and
(d) determining a predicted end of life of the electrochemical cell based on one of the calculated cell capacities being less than a predetermined percentage of the nominal capacity.

2. The method of claim 1 wherein:
the model does not include an algebraic equation.

3. The method of claim 1 wherein:
sequentially calculating the cell capacity at the end of each of the plurality of cell cycles is at least three times faster than a degradation model based on porous-electrode theory that includes an algebraic equation.

4. The method of claim 1 wherein:
the model does not include an algebraic equation for calculating a surface potential difference (Φ_{s,n}−Φₑ) where Φ_{s,n} denotes a potential of a solid phase of the anode, and Φₑ denotes a potential of a phase of the electrolyte.

5. The method of claim 1 wherein:
step (c) comprises sequentially calculating the cell capacity at the end of each of the plurality of cell cycles based on a solid electrolyte interphase kinetic rate constant (k_{SEI}), a solid electrolyte interphase layer diffusivity (D_{SEI}), and an active material particle cracking rate (β_{LAM}).

6. The method of claim 5 wherein:
step (c) comprises tuning the solid electrolyte interphase kinetic rate constant, the solid electrolyte interphase layer diffusivity, and the active material particle cracking rate to create a linear degradation path for the calculated cell capacities of the plurality of cell cycles.

7. The method of claim 5 wherein:
step (c) comprises tuning the solid electrolyte interphase kinetic rate constant, the solid electrolyte interphase layer diffusivity, and the active material particle cracking rate to create a self-limiting degradation path for the calculated cell capacities of the plurality of cell cycles.

8. The method of claim 5 wherein:
step (c) comprises tuning the solid electrolyte interphase kinetic rate constant, the solid electrolyte interphase layer diffusivity, and the active material particle cracking rate to create an accelerating degradation path for the calculated cell capacities of the plurality of cell cycles.

9. The method of claim 1 further comprising:
(e) selecting a different at least one cell component;
(f) sequentially calculating a second cell capacity at an end of each of the plurality of cell cycles based on the different at least one cell component;
(g) determining an additional predicted end of life of the electrochemical cell based on one of the calculated second cell capacities being less than the predetermined percentage of the nominal capacity;
(h) comparing the predicted end of life and the additional predicted end of life and selecting a preferred cell having a greater predicted end of life of the predicted end of life and the additional predicted end of life; and
(i) manufacturing the preferred cell.

10. The method of claim 1 wherein:
calculating the cell capacity employs the relationship:
cell capacity=Cₙ(Θₙ¹⁰⁰−Θₙ⁰),
where Cₙ denotes a capacity of the anode, Θₙ¹⁰⁰ denotes a scaled volumed-averaged negative particle concentration at 100% State of Charge, and Θₙ⁰ denotes a scaled volumed-averaged negative particle concentration at 0% State of Charge.

11. The method of claim 1 wherein:
step (c) comprises sequentially calculating the cell capacity at the end of at least a portion of the plurality of cell cycles based on the total cyclable cations, a solid electrolyte interphase thickness (δ_{SEI}), a porosity (ε_{s,n}) of a solid phase of the anode, and a porosity (ε_{s,p}) of a solid phase of the cathode.

12. The method of claim 1 wherein:
the model does not include an algebraic equation for calculating a surface potential difference (Φ_{s,n}−Φₑ) where Φ_{s,n} denotes a potential of a solid phase of the anode, and Φₑ denotes a potential of a phase of the electrolyte.

13. The method of claim 1 wherein:
the cations are lithium cations.

14. The method of claim 1 wherein:
the anode comprises an anode material selected from graphite, lithium titanium oxide, hard carbon, tin/cobalt alloys, silicon/carbon, or lithium metal, the electrolyte comprises a liquid electrolyte including a lithium compound in an organic solvent, and
the cathode comprises a cathode active material selected from (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, and (iii) materials having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811).

15. The method of claim 1 wherein:
the anode comprises graphite,
the electrolyte comprises a liquid electrolyte including a lithium compound in an organic solvent,
the lithium compound is selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf),
the organic solvent is selected from carbonate based solvents, ether based solvents, ionic liquids, and mixtures thereof,
the carbonate based solvent is selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate, and mixtures thereof, and
the ether based solvent is selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane and mixtures thereof.

16. A method for manufacturing an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles, the method comprising:
(a) selecting at least one cell component selected from the group consisting of electrolytes, cathode active materials, and anode active materials, the at least one cell component causing the degradation of the cell;
(b) determining a nominal discharge capacity for the cell at a state of health of 100%;
(c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the model uses a current density of cation intercalation as a variable without use of a current density of solid electrolyte interphase formation as a variable; and
(d) determining a predicted end of life of the electrochemical cell based on one of the calculated cell capacities being less than a predetermined percentage of the nominal capacity.

17. A method for manufacturing an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles, the method comprising:
(a) selecting at least one cell component selected from the group consisting of electrolytes, cathode active materials, and anode active materials, the at least one cell component causing the degradation of the cell;
(b) determining a nominal discharge capacity for the cell at a state of health of 100%;
(c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the model uses a current density of cation intercalation as a variable without use of a current density of cation plating as a variable; and
(d) determining a predicted end of life of the electrochemical cell based on one of the calculated cell capacities being less than a predetermined percentage of the nominal capacity.

18. A method for predicting an end of life of an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles, the method comprising:
(a) selecting at least one cell component selected from the group consisting of electrolytes, cathode active materials, and anode active materials, the at least one cell component causing the degradation of the cell;
(b) determining a nominal discharge capacity for the cell at a state of health of 100%;
(c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the cell cycles are initialized based on a rate of degradation over a plurality of previous cycles and wherein a time at which to simulate the next cycle is chosen based on the rate of degradation over the plurality of previous cycles; and
(d) determining a predicted end of life of the electrochemical cell based on one of the calculated cell capacities being less than a predetermined percentage of the nominal capacity.

19. A method for predicting an end of life of an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles, the method comprising:
(a) selecting at least one cell component selected from the group consisting of electrolytes, cathode active materials, and anode active materials, the at least one cell component causing the degradation of the cell;
(b) determining a nominal discharge capacity for the cell at a state of health of 100%;
(c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the model uses a current density of cation intercalation as a variable without use of a current density of solid electrolyte interphase formation as a variable; and
(d) determining a predicted end of life of the electrochemical cell based on one of the calculated cell capacities being less than a predetermined percentage of the nominal capacity.

20. A method for predicting an end of life of an electrochemical cell including an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles, the method comprising:
(a) selecting at least one cell component selected from the group consisting of electrolytes, cathode active materials, and anode active materials, the at least one cell component causing the degradation of the cell;
(b) determining a nominal discharge capacity for the cell at a state of health of 100%;
(c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the model uses a current density of cation intercalation as a variable without use of a current density of cation plating as a variable; and
(d) determining a predicted end of life of the electrochemical cell based on one of the calculated cell capacities being less than a predetermined percentage of the nominal capacity.

21. A method in a data processing system comprising at least one processor and at least one memory, the at least one memory comprising instructions executed by the at least one processor to implement an electrochemical cell end of life prediction system, wherein the electrochemical cell includes an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles, the method comprising:
(a) receiving a selection of at least one cell component selected from the group consisting of electrolytes, cathode active materials, and anode active materials, the at least one cell component causing the degradation of the cell;
(b) receiving a nominal discharge capacity for the cell at a state of health of 100%;
(c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the cell cycles are initialized based on a rate of degradation over a plurality of previous cycles and wherein a time at which to simulate the next cycle is chosen based on the rate of degradation over the plurality of previous cycles; and
(d) determining a predicted end of life of the electrochemical cell based on one of the calculated cell capacities being less than a predetermined percentage of the nominal capacity.

22. A method in a data processing system comprising at least one processor and at least one memory, the at least one memory comprising instructions executed by the at least one processor to implement an electrochemical cell end of life prediction system, wherein the electrochemical cell includes an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles, the method comprising:
(a) receiving a selection of at least one cell component selected from the group consisting of electrolytes, cathode active materials, and anode active materials, the at least one cell component causing the degradation of the cell;
(b) receiving a nominal discharge capacity for the cell at a state of health of 100%;
(c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the model uses a current density of cation intercalation as a variable without use of a current density of solid electrolyte interphase formation as a variable; and
(d) determining a predicted end of life of the electrochemical cell based on one of the calculated cell capacities being less than a predetermined percentage of the nominal capacity.

23. A method in a data processing system comprising at least one processor and at least one memory, the at least one memory comprising instructions executed by the at least one processor to implement an electrochemical cell end of life prediction system, wherein the electrochemical cell includes an anode, an electrolyte, and a cathode including cations that move from the cathode to the anode during a charging phase of each of a plurality of cell cycles, wherein the cell undergoes degradation that results in loss of active material and loss of cation inventory during one or more charging phases of the cell cycles, the method comprising:
(a) receiving a selection of at least one cell component selected from the group consisting of electrolytes, cathode active materials, and anode active materials, the at least one cell component causing the degradation of the cell;
(b) receiving a nominal discharge capacity for the cell at a state of health of 100%;
(c) sequentially calculating a cell capacity at an end of each of the plurality of cell cycles based on total cyclable cations (rqs), accessible storage sites in each electrode, and the at least one cell component using a degradation model based on porous-electrode theory and having one or more degradation pathways, wherein the model uses a current density of cation intercalation as a variable without use of a current density of cation plating as a variable; and
(d) determining a predicted end of life of the electrochemical cell based on one of the calculated cell capacities being less than a predetermined percentage of the nominal capacity.
